(19) United States
(12) Patent Application Publication
(10) Pub. No.: US 2025/0183868 A1
(43) Pub. Date: Jun. 5, 2025

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Sho NAGATOMO, Nagaokakyo-shi (JP)

(21) Appl. No.: 19/042,302

(22) Filed: Jan. 31, 2025

Related U.S. Application Data
(63) Continuation of application No. PCT/JP2023/030811, filed on Aug. 25, 2023.
(60) Provisional application No. 63/401,254, filed on Aug. 26, 2022.

(51) Int. Cl. H03H 9/02; H03H 9/13; H03H 9/17

(52) U.S. Cl. CPC H03H 9/02086; H03H 9/02031; H03H 9/02157; H03H 9/02228; H03H 9/132; H03H 9/173; H03H 9/175; H03H 9/176

(57) ABSTRACT

An acoustic wave device includes a piezoelectric film including a piezoelectric layer made of lithium niobate, a first interdigitated electrode including a first busbar and first electrode fingers, a second interdigitated electrode including a second busbar and second electrode fingers and interdigitated with the first electrode fingers, and a third electrode including third electrode fingers side by side with the first and second electrode fingers, connected to a potential different from potentials of the first and second interdigitated electrodes and a connection electrode connecting adjacent third electrode fingers to each other. The connection electrode connects ends of adjacent third electrode fingers closer to at least the first busbar. The connection electrode is between at least the first busbar and ends of the second electrode fingers. Mass-addition films are provided in at least a portion of at least one of first, second, and third gap regions.

### CROSS REFERENCE TO RELATED APPLICATIONS

This application claims the benefit of priority to Provisional Application No. 63/401,254 filed on Aug. 26, 2022 and is a Continuation Application of PCT Application No. PCT/JP2023/030811 filed on Aug. 25, 2023. The entire contents of each application are hereby incorporated herein by reference.

### BACKGROUND OF THE INVENTION

### 1. Field of the Invention

The present invention relates to acoustic wave devices.

### 2. Description of the Related Art

Conventionally, acoustic wave devices have been widely used in filters of mobile phones and the like. In recent years, acoustic wave devices using a bulk wave in a thickness-shear mode, as described in U.S. Pat. No. 10,491,192, have been proposed. In such an acoustic wave device, a piezoelectric layer is provided on a support body. Pairs of electrodes are provided on the piezoelectric layer. Each pair of electrodes faces each other on the piezoelectric layer and is connected to different potentials. A bulk wave in the thickness-shear mode is excited by an AC voltage being applied between the electrodes described above.

The acoustic wave device refers to, for example, an acoustic wave resonator and is used in, for example, a ladder filter. The electrostatic capacitance ratio between a plurality of acoustic wave resonators needs to be increased to obtain good characteristics in a ladder filter. In this case, the electrostatic capacitance of some of the acoustic wave resonators in the ladder filter needs to be increased.

For example, the acoustic wave resonators need to be enlarged to increase the electrostatic capacitance of the acoustic wave resonators. Accordingly, when the acoustic wave resonators are used in a ladder filter, the ladder filter is likely to become large. In particular, a ladder filter including acoustic wave resonators that have a small electrostatic capacitance and use a bulk wave in a thickness-shear mode becomes larger.

The inventors of example embodiments of the present invention have discovered that an acoustic wave device with the following structure has a suitable filter waveform without a filter device being enlarged when the acoustic wave device is used in the filter device. In this structure, an electrode connected to a potential that differs from an input potential and an output potential, such as a reference potential, is disposed between an electrode connected to the input potential and an electrode connected to the output potential.

In addition, the inventors of example embodiments of the present invention have also discovered that there is a concern that insertion loss is not sufficiently reduced even when the structure described above is simply adopted.

### SUMMARY OF THE INVENTION

Example embodiments of the present invention provide acoustic wave devices that each achieve size reduction of a filter device and reduce insertion loss.

According to an example embodiment of the present invention, an acoustic wave device includes a piezoelectric film including a piezoelectric layer made of lithium niobate, a first interdigitated electrode on the piezoelectric layer, the first interdigitated electrode including a first busbar and a plurality of first electrode fingers each including one end connected to the first busbar, a second interdigitated electrode on the piezoelectric layer, the second interdigitated electrode including a second busbar and a plurality of second electrode fingers each including one end connected to the second bus bar, the plurality of second electrode fingers being interdigitated with the plurality of first electrode fingers, and a third electrode including a plurality of third electrode fingers and a connection electrode, the plurality of third electrode fingers being provided on the piezoelectric layer side by side with the first electrode fingers and the second electrode fingers in a direction in which the first electrode fingers and the second electrode fingers are arranged in plan view, the connection electrode connecting adjacent third electrode fingers to each other, the third electrode being connected to a potential different from a potential of the first interdigitated electrode and a potential of the second interdigitated electrode, in which one of the first interdigitated electrode and the second interdigitated electrode is connected to an input potential and another of the second interdigitated electrode and the second interdigitated electrode is connected to an output potential, the first electrode fingers, the second electrode fingers, and the third electrode fingers are arranged in an order of the first electrode finger, the third electrode finger, the second electrode finger, and the third electrode finger to define one cycle when starting from the first electrode finger, the connection electrode connects, to each other, ends of the adjacent third electrode fingers closer to at least the first busbar, and the connection electrode is located between at least the first busbar and ends of the plurality of second electrode fingers, when a direction in which the first electrode fingers, the second electrode fingers, and the third electrode fingers extend is an electrode finger extension direction, and a direction orthogonal or substantially orthogonal to the electrode finger extension direction is an electrode finger orthogonal direction, a region, located between the ends of the plurality of second electrode fingers and the connection electrode in the electrode finger extension direction in plan view, that extends in the electrode finger orthogonal direction is a first gap region, a region, located between the connection electrode and the first busbar, that extends in the electrode finger orthogonal direction is a second gap region, and a mass-addition film is provided in at least a portion of at least one of the first gap region, the second gap region, and a region that is located between ends of the plurality of first electrode fingers and the second busbar in the electrode finger extension direction in plan view, does not include the connection electrode, and extends in the electrode finger orthogonal direction.

According to another example embodiment of the present invention, an acoustic wave device includes a piezoelectric film including a piezoelectric layer made of lithium niobate, a first interdigitated electrode on the piezoelectric layer, the first interdigitated electrode including a first busbar and a plurality of first electrode fingers each including one end connected to the first busbar, a second interdigitated electrode on the piezoelectric layer, the second interdigitated electrode including a second busbar and a plurality of second electrode fingers each including one end connected to the second bus bar, the plurality of second electrode fingers being interdigitated with the plurality of first electrode fingers, and a third electrode including a plurality of third electrode fingers and a connection electrode, the plurality of third electrode fingers being provided on the piezoelectric layer side by side with the first electrode fingers and the second electrode fingers in a direction in which the first electrode fingers and the second electrode fingers are arranged in plan view, the connection electrode connecting adjacent third electrode fingers to each other, the third electrode being connected to a potential different from a potential of the first interdigitated electrode and a potential of the second interdigitated electrode, in which one of the first interdigitated electrode and the second interdigitated electrode is connected to an input potential and another of the second interdigitated electrode and the second interdigitated electrode is connected to an output potential, the first electrode fingers, the second electrode fingers, and the third electrode fingers are arranged in an order of the first electrode finger, the third electrode finger, the second electrode finger, and the third electrode finger that define one cycle when starting from the first electrode finger, the connection electrode connects ends of the adjacent third electrode fingers closer to at least the first busbar to each other, and the connection electrode is located between at least the first busbar and ends of the plurality of second electrode fingers, when a direction in which the first electrode fingers, the second electrode fingers, and the third electrode fingers extend is an electrode finger extension direction, and a direction orthogonal or substantially orthogonal to the electrode finger extension direction is an electrode finger orthogonal direction, a region, located between the ends of the plurality of second electrode fingers and the connection electrode in the electrode finger extension direction in plan view, that extends in the electrode finger orthogonal direction is a first gap region, a region, located between the connection electrode and the first busbar, that extends in the electrode finger orthogonal direction is a second gap region, a through-hole is provided in the piezoelectric film in at least one of the first gap region, the second gap region, and a region that is located between ends of the plurality of first electrode fingers and the second busbar in the electrode finger extension direction in plan view, does not include the connection electrode, and extends in the electrode finger orthogonal direction, and, in the region in which the through-hole is provided in plan view, the through-hole is located in all of portions in which the first electrode fingers, the second electrode fingers, or the third electrode fingers are not provided.

According to example embodiments of the present invention, it is possible to provide acoustic wave devices that each achieve size reduction of a filter device and reduce insertion loss.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view of an acoustic wave device according to a first example embodiment of the present invention.

FIG. 2 is a schematic plan view of the acoustic wave device according to the first example embodiment of the present invention.

FIG. 3 is a schematic elevational cross-sectional view illustrating the vicinity of first to third electrode fingers in the first example embodiment of the present invention.

FIG. 4 is a diagram illustrating the bandpass characteristics of the acoustic wave devices according to the first example embodiment and a first comparative example of the present invention.

FIG. 5 is a diagram illustrating a map of the fractional bandwidth with respect to the Euler angles (0°, θ, ψ) of LiNbO₃ when d/p is infinitely brought close to 0.

FIG. 6 is a schematic plan view of an acoustic wave device according to a second example embodiment of the present invention.

FIG. 7 is a diagram illustrating the bandpass characteristics of the acoustic wave devices according to the second example embodiment and the first comparative example of the present invention.

FIG. 8 is a schematic plan view of an acoustic wave device according to a third example embodiment of the present invention.

FIG. 9 is a diagram illustrating the bandpass characteristics of the acoustic wave devices according to the third example embodiment and the first comparative example of the present invention.

FIG. 10 is a diagram illustrating the bandpass characteristics of acoustic wave devices according to a fourth example embodiment and a second comparative example of the present invention when the width of first to fourth gap regions is about 1.5 μm.

FIG. 11 is a diagram illustrating the bandpass characteristics of the acoustic wave devices according to the fourth example embodiment and the second comparative example of the present invention when the width of the first to fourth gap regions is about 5 μm.

FIG. 12 is a diagram illustrating the bandpass characteristics of acoustic wave devices according to a fifth example embodiment and the second comparative example of the present invention when the width of the first to fourth gap regions is about 1.5 μm.

FIG. 13 is a diagram illustrating the bandpass characteristics of the acoustic wave devices according to the fifth example embodiment and the second comparative example of the present invention when the width of the first to the fourth gap regions is about 5 μm.

FIG. 14 is a schematic plan view of an acoustic wave device according to a sixth example embodiment of the present invention.

FIG. 15 is a schematic plan view of an acoustic wave device according to a seventh example embodiment of the present invention.

FIG. 16 is a schematic plan view of an acoustic wave device according to an eighth example embodiment of the present invention.

FIG. 17 is a schematic plan view of an acoustic wave device according to a ninth example embodiment of the present invention.

FIG. 18 is a schematic plan view of an acoustic wave device according to a tenth example embodiment of the present invention.

FIG. 19 is a schematic plan view of a first acoustic wave resonator according to an eleventh example embodiment of the present invention.

FIG. 20 is a schematic elevational cross-sectional view illustrating the vicinity of the first to third electrode fingers in the eleventh example embodiment of the present invention.

FIG. 21 is a schematic plan view of an acoustic wave device according to a twelfth example embodiment of the present invention.

FIG. 22 is a diagram illustrating the bandpass characteristics of the acoustic wave devices according to the twelfth example embodiment and the first comparative example of the present invention.

FIG. 23 is a schematic plan view of an acoustic wave device according to a thirteenth example embodiment of the present invention.

FIG. 24 is a schematic plan view of an acoustic wave device according to a fourteenth example embodiment of the present invention.

FIG. 25 is a diagram illustrating the bandpass characteristics of the acoustic wave devices according to the fourteenth example embodiment and the first comparative example of the present invention.

FIG. 26 is a schematic plan view of an acoustic wave device according to a fifteenth example embodiment of the present invention.

FIG. 27A is a schematic perspective view illustrating the appearance of the acoustic wave device that uses a bulk wave in a thickness-shear mode, and FIG. 27B is a plan view illustrating an electrode structure on a piezoelectric layer.

FIG. 28 is a cross-sectional view taken along line A-A in FIG. 27A.

FIG. 29A is a schematic elevational cross-sectional view for describing a Lamb wave propagating through a piezoelectric film of the acoustic wave device, and FIG. 29B is a schematic elevational cross-sectional view for describing a bulk wave in the thickness-shear mode propagating through the piezoelectric film in the acoustic wave device.

FIG. 30 is a diagram illustrating an amplitude direction of a bulk wave in the thickness-shear mode.

FIG. 31 is a diagram illustrating resonance characteristics of the acoustic wave device that uses a bulk wave in the thickness-shear mode.

FIG. 32 is a diagram illustrating the relationship between d/p and a fractional bandwidth as a resonator when the center-to-center distance between adjacent electrodes is p and the thickness of the piezoelectric layer is d.

FIG. 33 is a plan view of the acoustic wave device that uses a bulk wave in the thickness-shear mode.

FIG. 34 is a diagram illustrating the resonance characteristics of an acoustic wave device according to a reference example in which spurious appears.

FIG. 35 is a diagram illustrating the relationship between the fractional bandwidth and the phase rotation amount of the impedance of spurious normalized by about 180 degrees as the level of the spurious.

FIG. 36 is a diagram illustrating the relationship between d/2p and a metallization ratio MR.

FIG. 37 is a diagram illustrating a map of the fractional bandwidth with respect to the Euler angles (0°, θ, ψ) of LiNbO₃ when d/p is infinitely brought close to 0.

FIG. 38 is an elevational cross-sectional view of an acoustic wave device including an acoustic multilayer film.

FIG. 39 is a partially cutaway perspective view for describing an acoustic wave device that uses a Lamb wave.

### DETAILED DESCRIPTION OF THE EXAMPLE EMBODIMENTS

The present invention will be clarified below by describing example embodiments of the present invention with reference to the drawings.

Example embodiments described in this specification are exemplary, and partial substitution or combination of components between different example embodiments is possible.

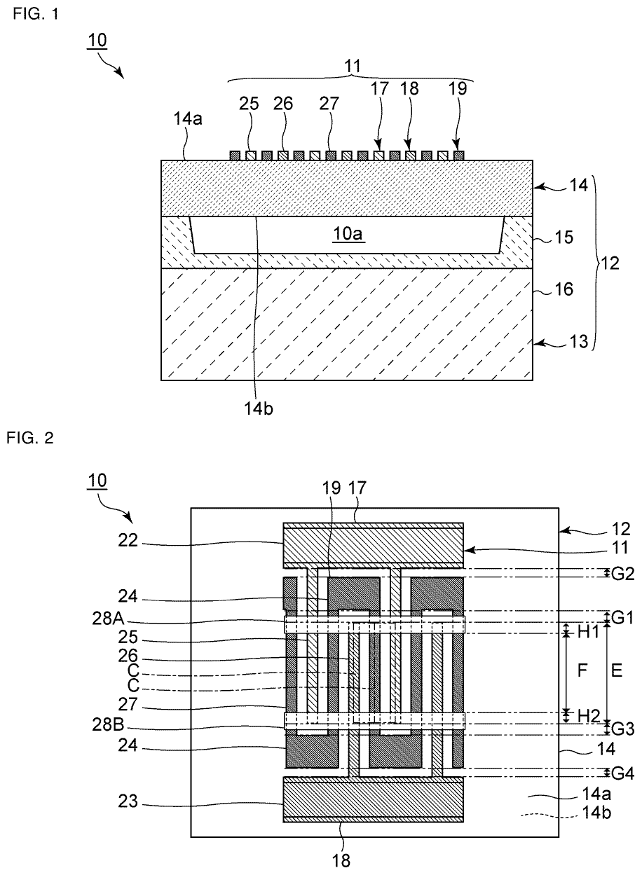

FIG. 1 is a schematic elevational cross-sectional view of an acoustic wave device according to a first example embodiment of the present invention. FIG. 2 is a schematic plan view of the acoustic wave device according to the first example embodiment. It should be noted that FIG. 1 is a schematic elevational cross-sectional view of a central region F of an overlap region E, which will be described later. In FIG. 2, electrodes are hatched. In schematic plan views other than FIG. 2, the electrodes may be hatched.

The acoustic wave device 10 illustrated in FIG. 1 is configured to be able to use a thickness-shear mode. The acoustic wave device 10 is an acoustically coupled filter. The structure of the acoustic wave device 10 will be described below.

The acoustic wave device 10 includes a piezoelectric substrate 12 and a functional electrode 11. The piezoelectric substrate 12 is a substrate with piezoelectricity. Specifically, the piezoelectric substrate 12 includes a support 13 and a piezoelectric layer 14 as a piezoelectric film. The piezoelectric layer 14 is a layer including a piezoelectric body. On the other hand, a piezoelectric film in this specification refers to a film with piezoelectricity and does not necessarily refer to a film including a piezoelectric body. However, in the present example embodiment, the piezoelectric film is the piezoelectric layer 14 including a single layer and is a film including a piezoelectric body. In an example embodiment of the present invention, the piezoelectric film may be a laminated film including the piezoelectric layer 14. In the present example embodiment, the support 13 includes a support substrate 16 and an insulation layer 15. The insulation layer 15 is provided on the support substrate 16. The piezoelectric layer 14 is provided on the insulation layer 15. However, the support 13 may include only the support substrate 16. The support 13 need not necessarily be provided.

The piezoelectric layer 14 includes a first main surface 14a and a second main surface 14b. The first main surface 14a and the second main surface 14b face away from each other. The second main surface 14b is located closer to the support 13 than is the first main surface 14a.

The piezoelectric layer 14 is made of lithium niobate, for example. More specifically, in the present example embodiment, the lithium niobate used in the piezoelectric layer 14 is, for example, Z-cut LiNbO₃. The Euler angles (φ, θ, ψ) of this LiNbO₃ are, for example, (0°, 0°, 90°). However, the Euler angles (φ, θ, ψ) of the piezoelectric layer 14 are not limited to those described above. In this specification, when a certain component is made of a certain material, a small amount of impurities that do not significantly degrade electrical characteristics of the acoustic wave device may be contained.

The functional electrode 11 is provided on the first main surface 14a of the piezoelectric layer 14. As illustrated in FIG. 2, the functional electrode 11 includes a pair of interdigitated electrodes and a third electrode 19. The pair of interdigitated electrodes specifically refers to a first interdigitated electrode 17 and a second interdigitated electrode 18. The first interdigitated electrode 17 is connected to an input potential. The second interdigitated electrode 18 is connected to an output potential. The third electrode 19 is connected to a reference potential in the present example embodiment. The third electrode 19 need not necessarily be connected to the reference potential. The third electrode 19 only needs to be connected to a potential that differs from the potential of the first interdigitated electrode 17 and the potential of the second interdigitated electrode 18. However, the third electrode 19 is preferably connected to the reference potential.

The first interdigitated electrode 17 may also be connected to the output potential. The second interdigitated electrode 18 may also be connected to the input potential. As described above, the first interdigitated electrode 17 only needs to be connected to one of the input potential and the output potential. The second interdigitated electrode 18 only needs to be connected to the other of the input potential and the output potential.

The first interdigitated electrode 17 and the second interdigitated electrode 18 are provided on the first main surface 14a of the piezoelectric layer 14. The first interdigitated electrode 17 includes a first busbar 22 and a plurality of first electrode fingers 25. One end of each of the plurality of first electrode fingers 25 is connected to the first busbar 22. The second interdigitated electrode 18 includes a second busbar 23 and a plurality of second electrode fingers 26. One end of each of the plurality of second electrode fingers 26 is connected to the second busbar 23.

The first busbar 22 and the second busbar 23 face each other. The plurality of first electrode fingers 25 and the plurality of second electrode fingers 26 are interdigitated with each other. The first electrode finger 25 and the second electrode finger 26 are arranged alternately in a direction orthogonal or substantially orthogonal to the direction in which the first electrode finger 25 and the second electrode finger 26 extend.

The third electrode 19 has a meandering shape. Specifically, the third electrode 19 includes a plurality of connection electrodes 24 and a plurality of third electrode fingers 27. The plurality of connection electrodes 24 and the plurality of third electrode fingers 27 are provided on the first main surface 14a of the piezoelectric layer 14. Adjacent third electrode fingers 27 are connected by each of the connection electrodes 24. Since this structure is repeated, the third electrode 19 has a meandering shape.

More specifically, the ends of two adjacent third electrode fingers 27 closer to the first busbar 22 or the ends thereof closer to the second busbar 23 are connected to each other by the connection electrode 24. For example, one connection electrode 24 is connected to each of the end closer to the first busbar 22 and the end closer to the second busbar 23 of the third electrode fingers 27 other than the third electrode fingers 27 at both ends in the orthogonal direction of the plurality of third electrode fingers 27. The third electrode finger 27 is connected to the third electrode fingers 27 on both sides of the third electrode finger 27 by the connection electrodes 24. Since this structure is repeated, the third electrode 39 has a meandering shape.

In an example embodiment of the present invention, the connection electrodes 24 only need to be located on at least a side closer to the first busbar 22. The connection electrodes 24 only need to electrically connect the plurality of third electrode fingers 27 to each other.

As illustrated in FIG. 2, the plurality of third electrode fingers 27 extend parallel or substantially parallel to the plurality of first electrode fingers 25 and the plurality of second electrode fingers 26. The plurality of third electrode fingers 27 are provided so as to be disposed side by side with the first electrode fingers 25 and the second electrode fingers 26 in the direction in which the first electrode fingers 25 and the second electrode fingers 26 are arranged. Accordingly, the first electrode fingers 25, the second electrode fingers 26, and the third electrode fingers 27 are arranged in one direction.

In the following description, the direction in which the first electrode fingers 25, the second electrode fingers 26, and the third electrode fingers 27 extend is an electrode finger extension direction, and the direction orthogonal or substantially orthogonal to the electrode finger extension direction is an electrode finger orthogonal direction. When the direction in which the first electrode fingers 25, the second electrode fingers 26, and the third electrode fingers 27 are arranged is an electrode finger arrangement direction, the electrode finger arrangement direction is parallel or substantially parallel to the electrode finger orthogonal direction. In this specification, the first electrode fingers 25, the second electrode fingers 26, and the third electrode fingers 27 may be collectively referred to simply as the electrode fingers.

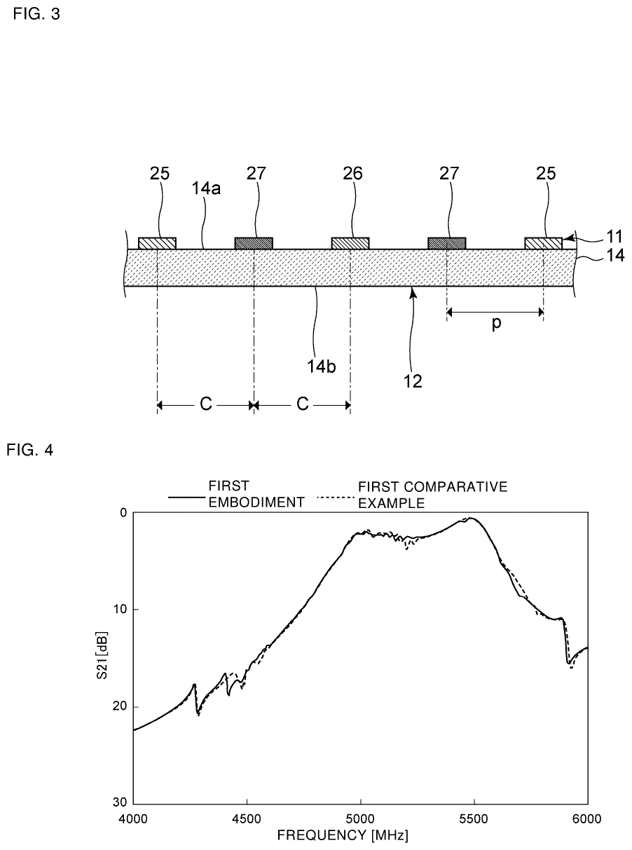

FIG. 3 is a schematic elevational cross-sectional view illustrating the vicinity of the first to third electrode fingers in the first example embodiment.

The plurality of electrode fingers are arranged in the order of the first electrode finger 25, the third electrode finger 27, the second electrode finger 26, and the third electrode finger 27 that constitute one cycle when starting from the first electrode finger 25. Accordingly, the plurality of electrode fingers are arranged in the order of the first electrode finger 25, the third electrode finger 27, the second electrode finger 26, the third electrode finger 27, the first electrode finger 25, the third electrode finger 27, and the second electrode finger 26, and so on. When the input potential, the output potential, and the reference potential are represented as IN, OUT, and GND, respectively, the order of the plurality of electrode fingers represented as the order of the potentials connected to the electrode fingers is IN, GND, OUT, GND, IN, GND, OUT, and so on.

In the present example embodiment, the electrode fingers located at both end portions in the electrode finger orthogonal direction in a region in which the plurality of electrode fingers are provided are both the third electrode finger 27. The electrode finger located at the end portion in the electrode finger orthogonal direction may be any one of the first electrode finger 25, the second electrode finger 26, and the third electrode finger 27.

In the present example embodiment, in the functional electrode 11, the center-to-center distances between a plurality of pairs of first electrode finger 25 and third electrode finger 27 adjacent to each other and the center-to-center distances between a plurality of pairs of second electrode finger 26 and third electrode finger 27 adjacent to each other are the same or substantially the same as each other. However, the center-to-center distances between adjacent electrode fingers need not be constant.

Each of the electrode fingers of the functional electrode 11 include a laminated metal film. Specifically, for example, in each of the electrode finger, a Ti layer, an AlCu layer, and a Ti layer are laminated together in this order as viewed from the piezoelectric layer 14. The materials of the electrode fingers are not limited to the materials described above. Alternatively, each of the electrode fingers may include a single metal layer.

In the present example embodiment, the ends of the plurality of second electrode fingers 26 face the connection electrodes 24 closer to the first busbar 22 with a gap therebetween in the electrode finger extension direction. The region, located between the ends of the plurality of second electrode fingers 26 and connection electrodes 24 in the electrode finger extension direction in plan view, that extends in the electrode finger orthogonal direction is a first gap region G1.

The connection electrodes 24 closer to the first busbar 22 face the first busbar 22 with a gap therebetween in the electrode finger extension direction. The region, located between the connection electrodes 24 and the first busbar 22 in plan view, that extends in the electrode finger orthogonal direction is a second gap region G2.

The ends of the plurality of first electrode fingers 25 face the connection electrodes 24 closer to the second busbar 23 with a gap therebetween in the electrode finger extension direction. The region, located between the ends of the plurality of first electrode fingers 25 and the connection electrodes 24 closer to the second busbar 23 in plan view, that extends in the electrode finger orthogonal direction is a third gap region G3.

The connection electrodes 24 closer to the second busbar 23 face the second busbar 23 with a gap therebetween in the electrode finger extension direction. The region, located between the connection electrodes 24 and the second busbar 23 in plan view, that extends in the electrode finger orthogonal direction is a fourth gap region G4. In the following description, the first gap region G1, the second gap region G2, the third gap region G3, and the fourth gap region G4 may be collectively referred to as simply the gap regions.

The acoustic wave device 10 is an acoustic wave resonator configured to be able to use a bulk wave in the thickness-shear mode. As illustrated in FIG. 2, the acoustic wave device 10 includes a plurality of excitation regions C. In the plurality of excitation regions C, bulk waves in the thickness-shear mode and acoustic waves in other modes are excited. FIG. 2 illustrates only two excitation regions C of the plurality of excitation regions C.

Some of the excitation regions C are regions in which the first electrode finger 25 and the third electrode finger 27 adjacent to each other overlap each other as viewed in the electrode finger orthogonal direction and regions located between the centers of the first electrode finger 25 and the third electrode finger 27 adjacent to each other. The remaining excitation regions C are regions in which the second electrode finger 26 and the third electrode finger 27 adjacent to each other overlap each other as viewed in the electrode finger orthogonal direction and regions located between the centers of the second electrode finger 26 and the third electrode finger 27 adjacent to each other. These excitation regions C are arranged in the electrode finger orthogonal direction.

In the functional electrode 11, the structure excluding the third electrode 19 is the same as or similar to the structure of an IDT (interdigital transducer) electrode. The region in which the first electrode finger 25 and the second electrode finger 26 adjacent to each other overlap each other as viewed in the electrode finger orthogonal direction is the overlap region E. However, the overlap region E is also the region in which the first electrode finger 25 and the third electrode finger 27 adjacent to each other or the second electrode finger 26 and the third electrode finger 27 adjacent to each other overlap each other as viewed in the electrode finger orthogonal direction. The overlap region E includes the plurality of excitation regions C. The overlap region E and the excitation regions C are the regions of the piezoelectric layer 14 that are defined in accordance with the structure of the functional electrode 11.

The overlap region E includes the central region F and a pair of edge regions. Specifically, the pair of edge regions refers to a first edge region H1 and a second edge region H2. The first edge region H1 and the second edge region H2 are disposed so as to face each other with the central region F therebetween in the electrode finger extension direction. The first edge region H1 is located closer to the first busbar 22. The second edge region H2 is located closer to the second busbar 23. The first edge region H1 is adjacent to the first gap region G1. The second edge region H2 is adjacent to the third gap region G3.

The plurality of third electrode fingers 27 extend to the outside of the overlap region E. Specifically, portions of the plurality of third electrode fingers 27 are located in the first gap region G1 and the third gap region G3.

The acoustic wave device 10 includes a pair of mass-addition films 28A and 28B. The mass-addition film 28A is provided over the first gap region G1 and the first edge region H1. The mass-addition film 28B is provided over the third gap region G3 and the second edge region H2. The mass-addition film 28A and the mass-addition films 28B are not provided in the central region F.

The mass-addition film 28A has a belt shape. Specifically, the mass-addition film 28A is provided over the first main surface 14a of the piezoelectric layer 14, the plurality of first electrode fingers 25, the plurality of second electrode fingers 26, and the plurality of third electrode fingers 27 in the first edge region H1. The mass-addition film 28A is provided over the first main surface 14a, the plurality of first electrode fingers 25, and the plurality of third electrode fingers 27 in the first gap region G1. The mass-addition film 28A is continuously provided so as to overlap the plurality of electrode fingers and inter-electrode-finger regions in plan view.

In this specification, plan view refers to view in the direction in which the support 13 and the piezoelectric film are laminated together from the top in FIG. 1. The top in FIG. 1 is closer to the piezoelectric layer 14 than to the support substrate 16. In addition, it is assumed that plan view in this specification is the same as a view in a main surface facing direction. The main surface facing direction refers to a direction in which the first main surface 14a and the second main surface 14b of the piezoelectric layer 14 face away from each other. More specifically, the main surface facing direction is a direction normal to, for example, the first main surface 14a.

The mass-addition film 28B is provided over the first main surface 14a of the piezoelectric layer 14 and the plurality of electrode fingers in the second edge region H2 and the third gap region G3. The mass-addition film 28B is continuously provided so as to overlap the plurality of electrode fingers and the inter-electrode-finger regions in plan view.

For example, silicon dioxide is used as the material of the mass-addition film 28A and the mass-addition film 28B. However, the material of the mass-addition film 28A and the mass-addition film 28B is not limited to the material described above.

The present example embodiment has the following structure. 1) The third electrode finger 27 of the third electrode 19 is provided between the first electrode finger 25 of the first interdigitated electrode 17 and the second electrode finger 26 of the second interdigitated electrode 18 in plan view. 2) The mass-addition film 28A and the mass-addition film 28B are provided in the first gap region G1 and the third gap region G3.

The mass-addition films only need to be provided in at least a portion of at least one of the first gap region G1, the second gap region G2, the third gap region G3, and the fourth gap region G4. Since the structure described above is provided in the present example embodiment, when the acoustic wave device 10 is used in the filter device, the size reduction of the filter device can be achieved and insertion loss can be reduced. The details of this advantageous effect will be described below by comparison between the present example embodiment and a first comparative example.

The first comparative example differs from the first example embodiment in that the mass-addition films are not provided. In the first comparative example, the piezoelectric layer is made of Z-cut lithium niobate. The bandpass characteristics were compared between the first example embodiment and the first comparative example. The design parameters of the acoustic wave device 10 having the structure of the first example embodiment are shown below.
Piezoelectric layer: material LiNbO₃, Euler angles (φ, θ, ψ) (0°, 0°, 90°), thickness about 400 nm
First to third electrode fingers: layer structure Ti layer, AlCu layer, Ti layer as viewed from piezoelectric layer, thickness of each layer about 10 nm, about 390 nm, about 4 nm as viewed from piezoelectric layer
Order of first to third electrode fingers represented by potential connected thereto: IN, GND, OUT, GND, and so on
Center-to-center distance between adjacent electrode fingers: about 1.4 μm
Duty ratio: about 0.3
Dimension of first edge region and second edge region in electrode finger extension direction: about 1 μm
Thickness of mass-addition film: about 25 nm

The design parameters in the first comparative example are the same or substantially the same as those in the first example embodiment except that the mass-addition films are not provided.

FIG. 4 is a diagram illustrating the bandpass characteristics of the acoustic wave devices according to the first example embodiment and the first comparative example. In FIG. 4, S21 bandpass characteristics are illustrated. The same applies to the diagrams illustrating the bandpass characteristics other than FIG. 4.

First, as illustrated in FIG. 4, it can be seen that a filter waveform is suitably obtained even in one acoustic wave device 10 according to the first example embodiment. The acoustic wave device 10 is an acoustically coupled filter. More specifically, as illustrated in FIG. 2, the acoustic wave device 10 includes the excitation region C located between the centers of the first electrode finger 25 and the third electrode finger 27 adjacent to each other and the excitation region C located between the centers of the second electrode finger 26 and the third electrode finger 27 adjacent to each other. In these excitation regions C, acoustic waves in a plurality of modes including a bulk wave in the thickness-shear mode are excited. A filter waveform can be suitably obtained even in one acoustic wave device 10 by these modes being coupled to each other.

Accordingly, even if the number of acoustic wave resonators of the filter device is small when the acoustic wave device 10 is used in the filter device, a filter waveform can be suitably obtained. Accordingly, the size reduction of the filter device can be achieved.

In addition, it can be seen that loss near the center of the pass band in the first example embodiment is smaller than that in the first comparative example, as illustrated in FIG. 4. Accordingly, when the acoustic wave device 10 is used in the filter device, insertion loss can be reduced.

The structure of the first example embodiment will be described in more detail below.

In the first example embodiment, the mass-addition film 28A is provided in a portion of the first gap region G1 in the electrode finger extension direction. The mass-addition film 28A is provided throughout the first gap region G1 in the electrode finger orthogonal direction.

The mass-addition film 28B is provided in a portion of the third gap region G3 in the electrode finger extension direction. The mass-addition film 28B is provided throughout the third gap region G3 in the electrode finger orthogonal direction.

However, as described above, the mass-addition films only need to be provided in at least a portion of at least one of the first gap region G1, the second gap region G2, the third gap region G3, and the fourth gap region G4. For example, the mass-addition film 28A only needs to be provided in at least a portion of the first gap region G1 in the electrode finger extension direction and at least a portion of the first gap region G1 in the electrode finger orthogonal direction. Alternatively, for example, only the mass-addition film 28A of the mass-addition film 28A and the mass-addition film 28B may be provided.

In the first example embodiment, the mass-addition film 28A is provided throughout the first edge region H1. The mass-addition film 28B is provided throughout the second edge region H2.

As illustrated in FIG. 1, the support 13 includes the support substrate 16 and the insulation layer 15. The piezoelectric substrate 12 is a laminated body in which the support substrate 16, the insulation layer 15, and the piezoelectric layer 14 are laminated together. That is, as viewed in a direction in which the first main surface 14a and the second main surface 14b of the piezoelectric layer 14 face away from each other, the piezoelectric layer 14 and the support 13 overlap each other.

The material of the support substrate 16 may be, for example, a semiconductor, such as silicon, or a ceramic, such as aluminum oxide. The material of the insulation layer 15 may be, for example, an appropriate dielectric, such as silicon oxide or tantalum oxide.

A recesses portion is provided in the insulation layer 15. A piezoelectric layer 14 as a piezoelectric film is provided on the insulation layer 15 so as to block the recessed portion. As a result, a hollow portion is provided. This hollow portion is a cavity portion 10a. In the first example embodiment, the support 13 and the piezoelectric film are disposed such that a portion of the support 13 and a portion of the piezoelectric film face each other with the cavity portion 10a therebetween. However, the recessed portion of the support 13 may also be provided over the insulation layer 15 and the support substrate 16. Alternatively, the recessed portion provided only in the support substrate 16 may also be blocked by the insulation layer 15. The recessed portion may also be provided in, for example, the piezoelectric layer 14. It should be noted that the cavity portion 10a may be a through-hole provided in the support 13.

The cavity portion 10a is, for example, an acoustic reflection portion. The acoustic reflection portion enables the energy of an acoustic wave to be effectively confined in a portion closer to the piezoelectric layer 14. The acoustic reflection portion only needs to be provided at a position on the support 13 that overlaps at least a portion of the functional electrode 11 in plan view. More specifically, in plan view, at least portions of the first electrode finger 25, the second electrode finger 26, and the third electrode finger 27 only need to overlap the acoustic reflection portion. In plan view, the plurality of excitation regions C preferably overlap the acoustic reflection portion.

The acoustic reflection portion may be an acoustic reflection film, such as an acoustic multilayer film, which will be described later. For example, an acoustic reflection film may be provided on a surface of the support.

As illustrated in FIG. 2, in the first example embodiment, in a portion in which the mass-addition film 28A and the electrode fingers are laminated together, the electrode fingers and the mass-addition film 28A are laminated together in this order as viewed from the piezoelectric layer 14. However, in a portion in which the mass-addition film 28A and the electrode fingers are laminated together, the mass-addition film 28A and the electrode fingers may be laminated together in this order as viewed from the piezoelectric layer 14. The same applies to a portion in which the mass-addition film 28B and the electrode fingers are laminated together.

As described above, the material of the mass-addition film 28A and the mass-addition film 28B is not limited to silicon dioxide. However, for example, at least one dielectric of silicon dioxide, tungsten oxide, niobium oxide, tantalum oxide, and hafnium oxide is preferably used as the material of the mass-addition film 28A and the mass-addition film 28B. As a result, insertion loss can be reduced with greater certainty when the acoustic wave device 10 is used in the filter device.

In the functional electrode 11, the center-to-center distance between adjacent electrode fingers is constant. However, the center-to-center distance between adjacent electrode fingers need not be constant. In this case, p is the longest distance among the center-to-center distance between the first electrode finger 25 and the third electrode finger 27 adjacent to each other and the center-to-center distance between the second electrode finger 26 and the third electrode finger 27 adjacent to each other. However, when the center-to-center distance between adjacent electrode fingers is constant as in the first example embodiment, the center-to-center distance between any pair of adjacent electrode fingers is distance p.

When the thickness of the piezoelectric film is d, d/p is, for example, preferably about 0.5 or less, and more preferably about 0.24 or less. As a result, a bulk wave in the thickness-shear mode is suitably excited. In the present example embodiment, the thickness d is the thickness of the piezoelectric layer 14.

An acoustic wave device according to an example embodiment of the present invention need not necessarily be configured to be able to use a bulk wave in the thickness-shear mode. The acoustic wave device may be configured to be able to use a plate wave. In this case, the excitation region is the overlap region E illustrated in FIG. 2.

In the first example embodiment, for example, the piezoelectric layer 14 is made of Z-cut LiNbO₃. However, the piezoelectric layer 14 may also be made of, for example, rotated Y-cut lithium niobate. In this case, the fractional bandwidth of the acoustic wave device 10 depends on the Euler angles (φ, θ, ψ) of the lithium niobate used in the piezoelectric layer 14. When the resonant frequency is fr and the anti-resonant frequency is fa, the fractional bandwidth is represented by (|fa−fr|/fr)×100%.

The relationship between the fractional bandwidth of the acoustic wave device 10 and the Euler angles (φ, θ, ψ) of the piezoelectric layer 14 was derived when d/p is infinitely brought close to 0. It should be noted that φ of the Euler angles was set to 0°.

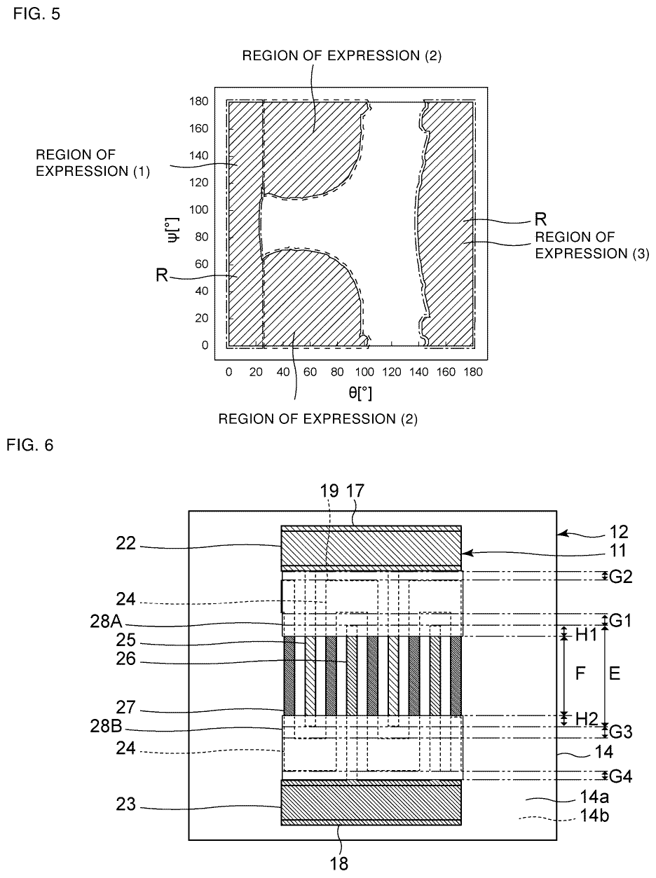

FIG. 5 is a diagram illustrating a map of the fractional bandwidth with respect to the Euler angles (0°, θ, ψ) of LiNbO₃ when d/p is infinitely brought close to 0.

Hatched regions R indicated in FIG. 5 are regions in which a fractional bandwidth of at least 2% or more can be obtained. The ranges of the regions R are approximated by expression (1), expression (2), and expression (3). It should be noted that, when φ of the Euler angles (φ, θ, ψ) falls within the range of about 0°±10°, the relationship between θ, ψ, and the fractional bandwidth is the same as the relationship illustrated in FIG. 5.

(within range of 0°±10°, 0° to 25°, any given ψ) expression (1)

(within range of 0°±10°, 25° to 100°, 0° to 75° [(1−(θ−50)²/2500)]^{1/2} or 180°−750[(1−(θ−50)²/2500)]^{1/2} to 180°) expression (2)

(within range of 0°±10°, 180®−40° [(1−(ψ−90)²/8100)]^{1/2} to 180°, any given ψ) expression (3)

The range of the Euler angles represented by expression (1), expression (2), or expression (3) is preferable. As a result, the fractional bandwidth can be sufficiently widened. As a result, the acoustic wave device 10 can be suitably used in a filter device.

Second to fifth example embodiments of the present invention will be described below. The second to fifth example embodiments differ from the first example embodiment in at least one of the positions of the mass-addition film 28A and the mass-addition film 28B and the material of the piezoelectric layer 14. Specifically, the piezoelectric layer 14 is made of Z-cut lithium niobate in the second example embodiment and the third example embodiment, but the piezoelectric layer 14 is made of rotated Y-cut lithium niobate in the fourth example embodiment and the fifth example embodiment.

The acoustic wave devices according to the second to fifth example embodiments have the same or substantially the same structure as the acoustic wave device according to the first example embodiment with the exception of the point described above.

In the second to fifth example embodiments, the mass-addition film 28A and the mass-addition film 28B are provided in any of the gap regions. Accordingly, also in the second to fifth example embodiments, when the acoustic wave device is used in the filter device, the size reduction of the filter device can be achieved and insertion loss can be reduced as in the first example embodiment.

In the second to fifth example embodiments, in the gap region in which the mass-addition film 28A is provided, the mass-addition film 28A is provided throughout the gap region in the electrode finger orthogonal direction. Similarly, in the gap region in which the mass-addition film 28B is provided, the mass-addition film 28B is provided throughout the gap region in the electrode finger orthogonal direction.

FIG. 6 is a schematic plan view of the acoustic wave device according to the second example embodiment.

The present example embodiment differs from the first example embodiment in that the mass-addition film 28A is provided over the first edge region H1, the first gap region G1, and the second gap region G2. The present example embodiment differs from the first example embodiment also in that the mass-addition film 28B is provided over the second edge region H2, the third gap region G3, and the fourth gap region G4.

The mass-addition film 28A is continuously provided from the first edge region H1 to the second gap region G2 in the electrode finger extension direction. Accordingly, the mass-addition film 28A overlaps the connection electrode 24 closer to the first busbar 22 in plan view. The mass-addition film 28A is provided throughout the first gap region G1 and the second gap region G2 in the electrode finger extension direction.

The mass-addition film 28B is continuously provided from the second edge region H2 to the fourth gap region G4 in the electrode finger extension direction. Accordingly, the mass-addition film 28B overlaps the connection electrode 24 closer to the second busbar 23 in plan view. The mass-addition film 28B is provided throughout the third gap region G3 and the fourth gap region G4 in the electrode finger extension direction.

The bandpass characteristics were compared between the second example embodiment and the first comparative example. The design parameters of the acoustic wave device having the structure of the second example embodiment are shown below. It should be noted that the design parameters are the same or substantially the same as the design parameters in the first example embodiment concerning comparison illustrated in FIG. 4.
Piezoelectric layer: material LiNbO₃, Euler angles (φ, θ, ψ) (0°, 0°, 90°), thickness about 400 nm
First to third electrode fingers: layer structure Ti layer, AlCu layer, Ti layer as viewed from piezoelectric layer, thickness of each layer about 10 nm, about 390 nm, about 4 nm as viewed from piezoelectric layer
Order of first to third electrode fingers represented by potential connected thereto: IN, GND, OUT, GND, and so on
Center-to-center distance between adjacent electrode fingers: about 1.4 μm
Duty ratio: about 0.3
Dimension of first edge region and second edge region in electrode finger extension direction: about 1 μm
Thickness of mass-addition film: about 25 nm

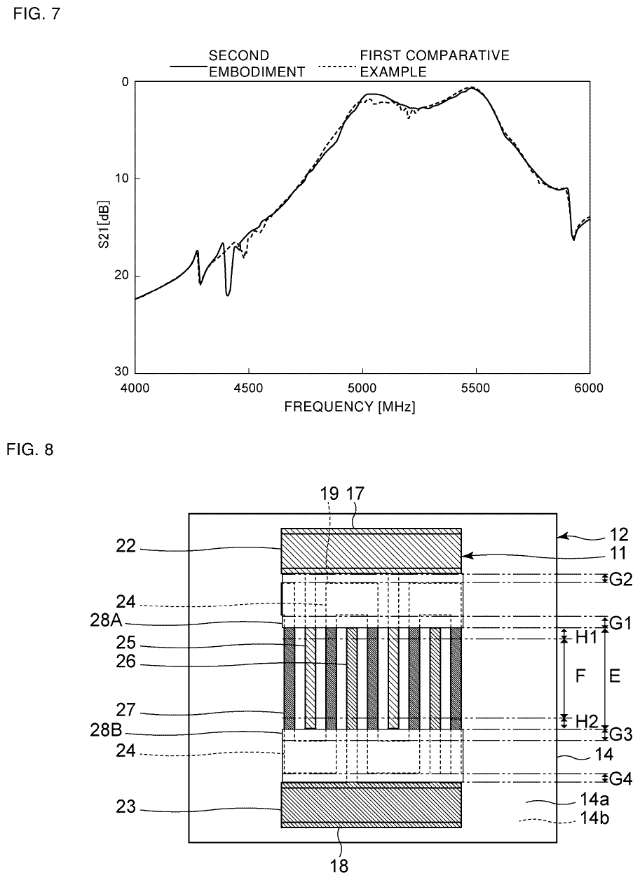

FIG. 7 is a diagram illustrating the bandpass characteristics of the acoustic wave devices according to the second example embodiment and the first comparative example.

It can be seen that loss near the center and on the low-frequency side of the pass band in the second example embodiment is smaller than that in the first comparative example as illustrated in FIG. 7.

FIG. 8 is a schematic plan view of the acoustic wave device according to the third example embodiment.

The present example embodiment differs from the first example embodiment in that the mass-addition film 28A is not provided in the first edge region H1, but is provided over the first gap region G1 and the second gap region G2. The present example embodiment differs from the first example embodiment also in that the mass-addition film 28B is not provided in the second edge region H2, but is provided over the third gap region G3 and the fourth gap region G4.

The mass-addition film 28A is continuously provided from the first gap region G1 to the second gap region G2 in the electrode finger extension direction. Accordingly, the mass-addition film 28A overlaps the connection electrode 24 closer to the first busbar 22 in plan view. The mass-addition film 28A is provided throughout the first gap region G1 and the second gap region G2 in the electrode finger extension direction.

The mass-addition film 28B is continuously provided from the third gap region G3 to the fourth gap region G4 in the electrode finger extension direction. Accordingly, the mass-addition film 28B overlaps the connection electrode 24 closer to the second busbar 23 in plan view. The mass-addition film 28B is provided throughout the third gap region G3 and the fourth gap region G4 in the electrode finger extension direction.

The bandpass characteristics were compared between the third example embodiment and the first comparative example. The design parameters of the acoustic wave device having the structure of the third example embodiment are the same or substantially the same as the design parameters in the first example embodiment concerning comparison illustrated in FIG. 4.

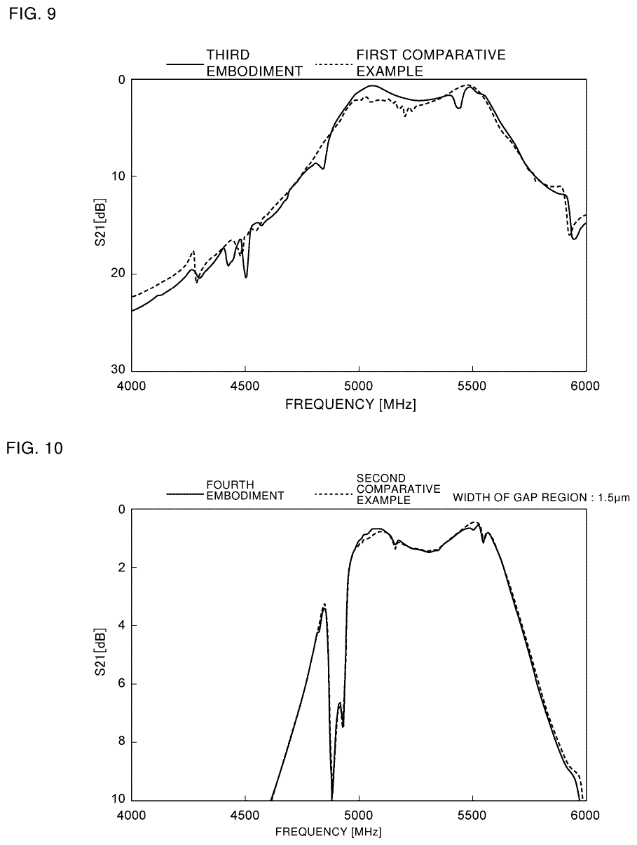

FIG. 9 is a diagram illustrating the bandpass characteristics of the acoustic wave devices according to the third example embodiment and the first comparative example.

It can be seen that loss near the center and on the low-frequency side of the pass band in the third example embodiment is smaller than that in the first comparative example as illustrated in FIG. 9.

The fourth example embodiment will be described below. In the fourth example embodiment, the positions of the mass-addition films are the same as those in the first example embodiment illustrated in FIG. 2. The fourth example embodiment differs from the first example embodiment in that the piezoelectric layer is made of rotated Y-cut lithium niobate.

The bandpass characteristics were compared between the fourth example embodiment and the second comparative example. The second comparative example differs from the fourth example embodiment in that the mass-addition films are not provided. In the second comparative example, the piezoelectric layer is made of rotated Y-cut lithium niobate.

In the comparison, the width of the first to fourth gap regions was set to either of two values. The width of the gap regions is the dimension of the gap regions in the electrode finger extension direction. In one comparison, the width of the first to fourth gap regions was set to about 1.5 μm. In the other comparison, the width of the first to fourth gap regions was set to about 5 μm. The design parameters of the acoustic wave device having the structure of the fourth example embodiment are shown below.
Piezoelectric layer: material LiNbO₃, Euler angles (φ, θ, ψ) (0°, 217.5°, 0°), thickness about 400 nm
First to third electrode fingers: layer structure Ti layer, AlCu layer, Ti layer as viewed from piezoelectric layer, thickness of each layer about 10 nm, about 390 nm, about 4 nm as viewed from piezoelectric layer
Order of first to third electrode fingers represented by potential connected thereto: IN, GND, OUT, GND, and so on
Center-to-center distance between adjacent electrode fingers: about 1.4 μm
Duty ratio: about 0.3
Dimension of first edge region and second edge region in electrode finger extension direction: about 1 μm
Width of first to fourth gap regions: about 1.5 μm or about 5 μm
Thickness of mass-addition film: about 25 nm

The design parameters in the second comparative example are the same or substantially the same as those in the fourth example embodiment except that the mass-addition films are not provided.

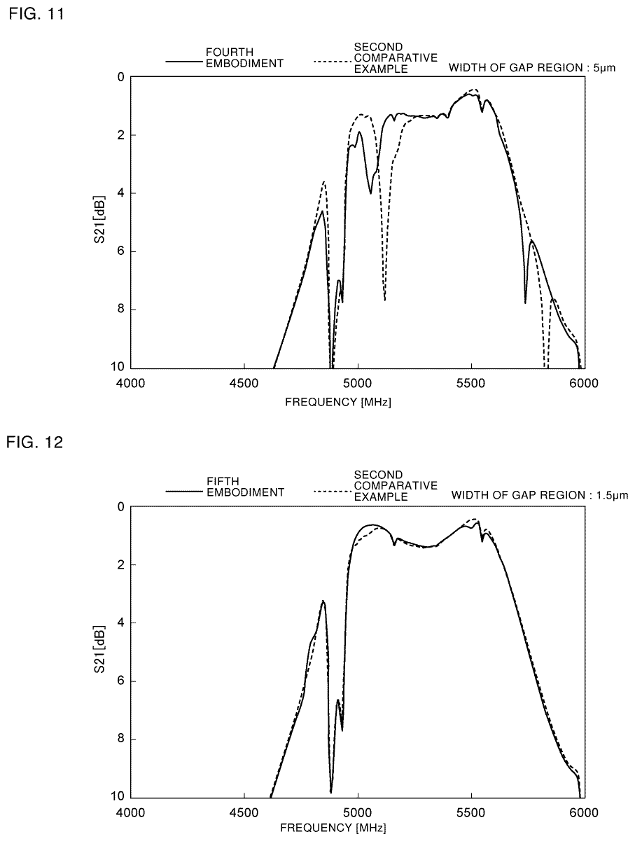

FIG. 10 is a diagram illustrating the bandpass characteristics of the acoustic wave devices according to the fourth example embodiment and the second comparative example when the width of the first to fourth gap regions is about 1.5 μm. FIG. 11 is a diagram illustrating the bandpass characteristics of the acoustic wave devices according to the fourth example embodiment and the second comparative example when the width of the first to fourth gap regions is about 5 μm.

As illustrated in FIG. 10, when the width of the first to fourth gap regions is about 1.5 μm, loss on the high-frequency side and the low-frequency side of the pass band in the fourth example embodiment can be further reduced than that in the second comparative example.

As illustrated in FIG. 11, when the width of the first to fourth gap regions is about 5 μm, large ripple occurs within the pass band in the bandpass characteristics in the second comparative example. In contrast, in the bandpass characteristics in the fourth example embodiment, the ripple within the pass band is smaller than the ripple in the second comparative example. Accordingly, loss can be reduced in the fourth example embodiment.

However, it can be seen from comparison between FIGS. 10 and 11 that, since the width of the first to fourth gap regions is small when the piezoelectric layer is made of rotated Y-cut lithium niobate, the ripple in the pass band can be further reduced or prevented.

The fifth example embodiment will be described below. In the fifth example embodiment, the positions of the mass-addition films are the same or substantially the same as those in the second example embodiment illustrated in FIG. 6. The fifth example embodiment differs from the second example embodiment in that the piezoelectric layer is made of rotated Y-cut lithium niobate.

The bandpass characteristics were compared between the fifth example embodiment and the second comparative example. In the comparison, the width of the first to fourth gap regions was set to either of two values. In one comparison, the width of the first to fourth gap regions was set to about 1.5 μm. In the other comparison, the width of the first to fourth gap regions was set to about 5 μm. The design parameters of the acoustic wave device having the structure of the fifth example embodiment are the same as the design parameters in the fourth example embodiment concerning comparison illustrated in FIGS. 10 and 11.

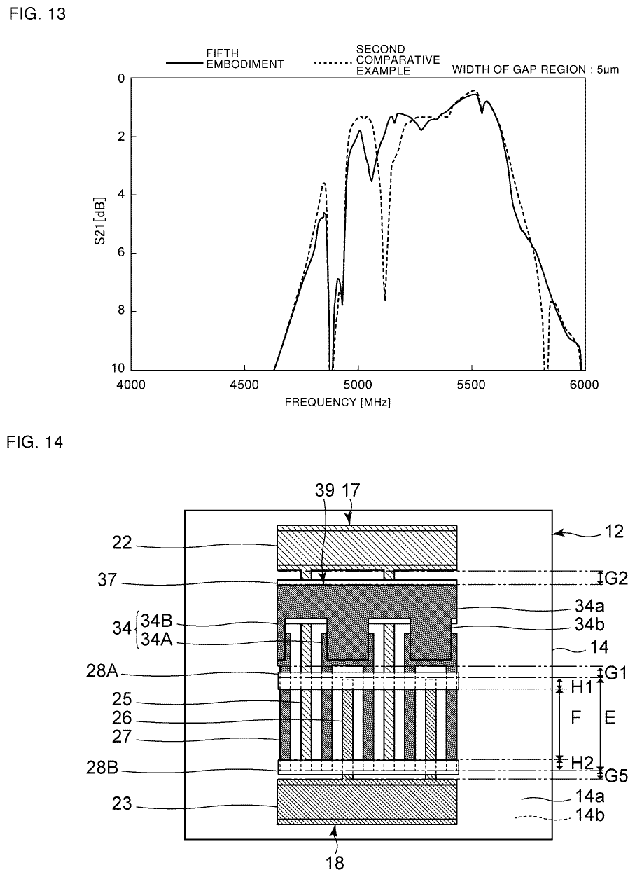

FIG. 12 is a diagram illustrating the bandpass characteristics of the acoustic wave devices according to the fifth example embodiment and the second comparative example when the width of the first to fourth gap regions is about 1.5 μm. FIG. 13 is a diagram illustrating the bandpass characteristics of the acoustic wave devices according to the fifth example embodiment and the second comparative example when the width of the first to the fourth gap regions is about 5 μm.

As illustrated in FIG. 12, when the width of the first to fourth gap regions is about 1.5 μm, loss on the high-frequency side and the low-frequency side of the pass band in the fifth example embodiment can be further reduced than that in the second comparative example.

As illustrated in FIG. 13, when the width of the first to fourth gap regions is about 5 μm, large ripple occurs within the pass band in the bandpass characteristics in the second comparative example. In contrast, in the bandpass characteristics in the fifth example embodiment, the ripple within the pass band is smaller than the ripple in the second comparative example. Accordingly, loss can be reduced in the fifth example embodiment.

However, it can be seen from comparison between FIG. 12 and FIG. 13 that, since the width of the first to fourth gap regions is small when the piezoelectric layer is made of rotated Y-cut lithium niobate, the ripple in the pass band can be further suppressed.

In the first to fifth example embodiments, the third electrode 19 has a meandering shape as illustrated in, for example, FIG. 2. Some of the plurality of connection electrodes 24 of the third electrodes 19 are provided between the ends of the plurality of second electrode fingers 26 and the first busbar 22. The remaining connection electrodes 24 are provided between the ends of the plurality of first electrode fingers 25 and the second busbar 23.

However, the third electrode 19 need not necessarily have a meandering shape. The connection electrodes 24 only need to be provided at least between the ends of the plurality of second electrode fingers 26 and the first busbar 22. When the connection electrodes 24 are not provided between the ends of the plurality of first electrode fingers 25 and the second busbar 23, the third gap region G3 and fourth gap region are not provided. An example in which the third electrode 19 does not have a meandering shape is illustrated in a sixth example embodiment of the present invention.

FIG. 14 is a schematic plan view of the acoustic wave device according to the sixth example embodiment.

The present example embodiment differs from the first example embodiment in the structure of the third electrode 39. The present example embodiment differs from the first example embodiment also in that the third gap region G3 and the fourth gap region G4 are not provided, but a fifth gap region G5 is provided. Accordingly, the present example embodiment differs from the first example embodiment also in the positions of the mass-addition films. The acoustic wave device according to the present example embodiment has the same or substantially the same structure as the acoustic wave device 10 according to the first example embodiment with the exception of the point described above.

In the third electrode 39, the connection electrode is a third busbar 34. The third busbar 34 as the connection electrode of the third electrode 39 electrically connects the plurality of third electrode fingers 27 to each other. Specifically, the third busbar 34 is located in a region between the first busbar 22 and the ends of the plurality of second electrode fingers 26. The plurality of first electrode fingers 25 are also located in this region. However, the third busbar 34 and the plurality of first electrode fingers 25 are electrically insulated from each other by the insulation film 37.

More specifically, the third busbar 34 includes a plurality of first connection electrodes 34A and one second connection electrode 34B. Each of the first connection electrodes 34A connects the ends of two adjacent third electrode fingers 27 to each other. A U-shaped electrode is provided by the first connection electrode 34A and the two third electrode fingers 27. The plurality of first connection electrodes 34A are connected to each other by the second connection electrode 34B. The insulation film 37 is provided between this second connection electrode 34B and the plurality of first electrode fingers 25.

More specifically, the insulation film 37 is provided on the first main surface 14a of the piezoelectric layer 14 so as to cover portions of the plurality of first electrode fingers 25. The insulation film 37 is provided in a region between the first busbar 22 and the ends of the plurality of second electrode fingers 26. The insulation film 37 has a belt shape.

The insulation film 37 does not cover the first connection electrode 34A of the third electrode 39. In addition, the second connection electrode 34B is provided over the insulation film 37 and the plurality of first connection electrodes 34A. More specifically, the second connection electrode 34B includes a bar portion 34a and a plurality of projecting portions 34b. The projecting portions 34b extend toward the first connection electrodes 34A from the bar portion 34a. The projecting portions 34b are connected to the first connection electrodes 34A, respectively. As a result, the plurality of third electrode fingers 27 are electrically connected to each other by the first connection electrodes 34A and the second connection electrodes 34B.

In the present example embodiment, the third busbar 34 is located in a region between the first busbar 22 and the ends of the plurality of second electrode fingers 26. Accordingly, the ends of the plurality of second electrode fingers 26 face the third busbar 34 with a gap therebetween in the electrode finger extension direction. On the other hand, the ends of the plurality of first electrode fingers 25 face the second busbar 23 with a gap therebetween in the electrode finger extension direction.

The region, located between the ends of the plurality of first electrode fingers 25 and the second busbar 23 in the electrode finger extension direction in plan view, that extends in the electrode finger orthogonal direction is a fifth gap region G5. The fifth gap region G5 is adjacent to the second edge region H2.

The first gap region G1 and the second gap region G2 are provided similarly to those in the first example embodiment. Specifically, the region, located between the ends of the plurality of second electrode fingers 26 and the third busbar 34 as the connection electrode in the electrode finger extension direction in plan view, that extends in the electrode finger orthogonal direction is the first gap region G1. The region, located between the third busbar 34 and the first busbar 22 in plan view, that extends in the electrode finger orthogonal direction is the second gap region G2. In the following description, the fifth gap region G5 and other gap regions may be collectively referred to as simply the gap regions.

The third gap region G3 and the fourth gap region G4 illustrated in FIG. 2 and the fifth gap region G5 coincide with each other in the following points. These regions are located between the ends of the plurality of first electrode fingers 25 and the second busbar 23, do not include the connection electrode, and extend in the electrode finger orthogonal direction.

As illustrated in FIG. 14, the mass-addition film 28A is provided over the first gap region G1 and the first edge region H1. The mass-addition film 28B is provided over the fifth gap region G5 and the second edge region H2.

The present example embodiment has the following structure. 1) The third electrode finger 27 of the third electrode 19 is provided between the first electrode finger 25 of the first interdigitated electrode 17 and the second electrode finger 26 of the second interdigitated electrode 18 in plan view. 2) The mass-addition film 28A and the mass-addition film 28B are provided in the first gap region G1 and the fifth gap region G5.

The mass-addition films only need to be provided in at least a portion of at least one of the first gap region G1, the second gap region G2, and the fifth gap region G5. Since the structure described above is provided in the present example embodiment, when the acoustic wave device is used in the filter device, the size reduction of the filter device can be achieved and insertion loss can be reduced.

In the first to sixth example embodiments, the mass-addition film 28A and the mass-addition film 28B have a belt shape. The mass-addition film 28A and the mass-addition film 28B each overlap the plurality of first electrode fingers 25, the plurality of second electrode fingers 26, and the plurality of third electrode fingers 27 as viewed in the electrode finger extension direction. However, the mass-addition film is not limited to belt-shaped. Examples in which the mass-addition film is not belt-shaped are illustrated in the seventh to tenth example embodiments.

The seventh example embodiment and the eighth example embodiment differ from the first example embodiment only in the positions of the mass-addition films. However, in the seventh example embodiment and the eighth example embodiment, the mass-addition films are provided in at least a portion of at least one of the first gap region G1, the second gap region G2, the third gap region G3, and the fourth gap region G4.

The ninth example embodiment and the tenth example embodiment differ from the sixth example embodiment only in the positions of the mass-addition films. However, in the ninth example embodiment and the tenth example embodiment, the mass-addition films are provided in at least a portion of at least one of the first gap region G1, the second gap region G2, and the fifth gap region G5. Also in the seventh to tenth example embodiments, when the acoustic wave device is used in the filter device, the size reduction of the filter device can be achieved and insertion loss can be reduced as in the first example embodiment or the sixth example embodiment.

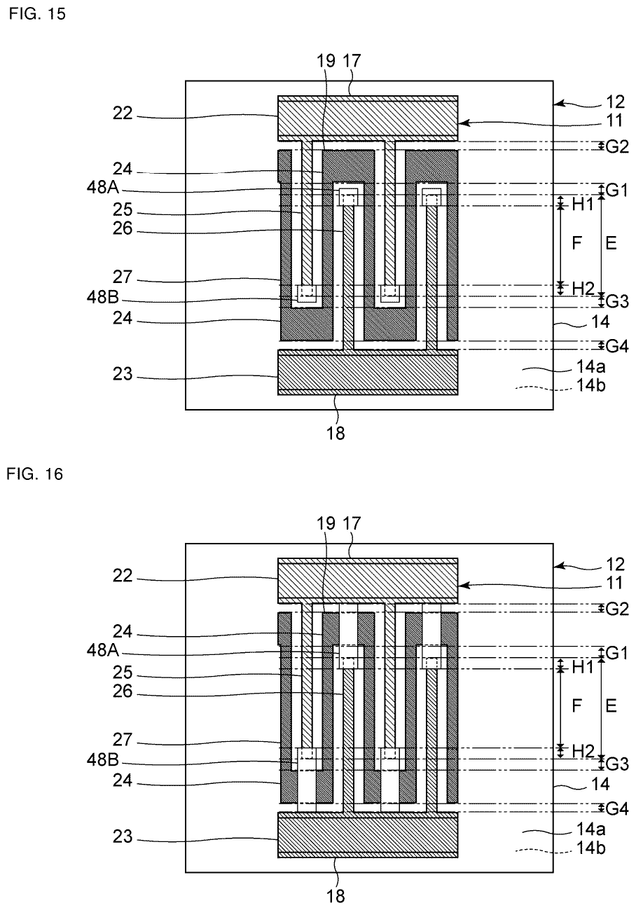

FIG. 15 is a schematic plan view of the acoustic wave device according to the seventh example embodiment.

The present example embodiment differs from the first example embodiment in the positions of a first mass-addition film 48A and a mass-addition film 48B. The acoustic wave device according to the present example embodiment has the same or substantially the same structure as the acoustic wave device 10 according to the first example embodiment with the exception of the point described above. In the present example embodiment, the first gap region G1, the second gap region G2, the third gap region G3, and the fourth gap region G4 are provided.

In the present example embodiment, the plurality of mass-addition films 48A are provided over the first gap region G1 and the first edge region H1. The plurality of mass-addition films 48A are arranged in the electrode finger orthogonal direction. On the other hand, the mass-addition films 48A are not provided in the second gap region G2.

Each of the mass-addition films 48A overlaps one of the plurality of first electrode fingers as viewed in the electrode finger extension direction. Each of the mass-addition films 48A overlaps one of the second electrode fingers 26 in plan view. The mass-addition film 48A may overlap the first electrode finger 25 or the third electrode finger 27 in plan view.

The plurality of mass-addition films 48B are provided over the third gap region G3 and the second edge region H2. The plurality of mass-addition films 48B are arranged in the electrode finger orthogonal direction. On the other hand, the mass-addition films 48B are not provided in the fourth gap region G4.

Each of the mass-addition films 48B overlaps one of the plurality of first electrode fingers as viewed in the electrode finger extension direction. Each of the mass-addition films 48B overlaps one of the first electrode fingers 25 in plan view. The mass-addition film 48B may overlap the second electrode finger 26 or the third electrode finger 27 in plan view.

FIG. 16 is a schematic plan view of the acoustic wave device according to the eighth example embodiment.

The present example embodiment differs from the seventh example embodiment in that the mass-addition film 48A is provided over the first edge region H1, the first gap region G1, and the second gap region G2. The present example embodiment differs from the seventh example embodiment also in that the mass-addition film 48B is provided over the second edge region H2, the third gap region G3, and the fourth gap region G4. The acoustic wave device according to the present example embodiment has the same or substantially the same structure as the acoustic wave device according to the seventh example embodiment with the exception of the point described above.

The mass-addition film 48A is continuously provided from the first edge region H1 to the second gap region G2 in the electrode finger extension direction. The mass-addition film 48A overlaps the connection electrode 24 closer to the first busbar 22 in plan view. The mass-addition film 48A is provided throughout the first gap region G1 and the second gap region G2 in the electrode finger extension direction.

The mass-addition film 48B is continuously provided from the second edge region H2 to the fourth gap region G4 in the electrode finger extension direction. The mass-addition film 48B overlaps the connection electrode 24 closer to the second busbar 23 in plan view. The mass-addition film 48B is provided throughout the third gap region G3 and the fourth gap region G4 in the electrode finger extension direction.

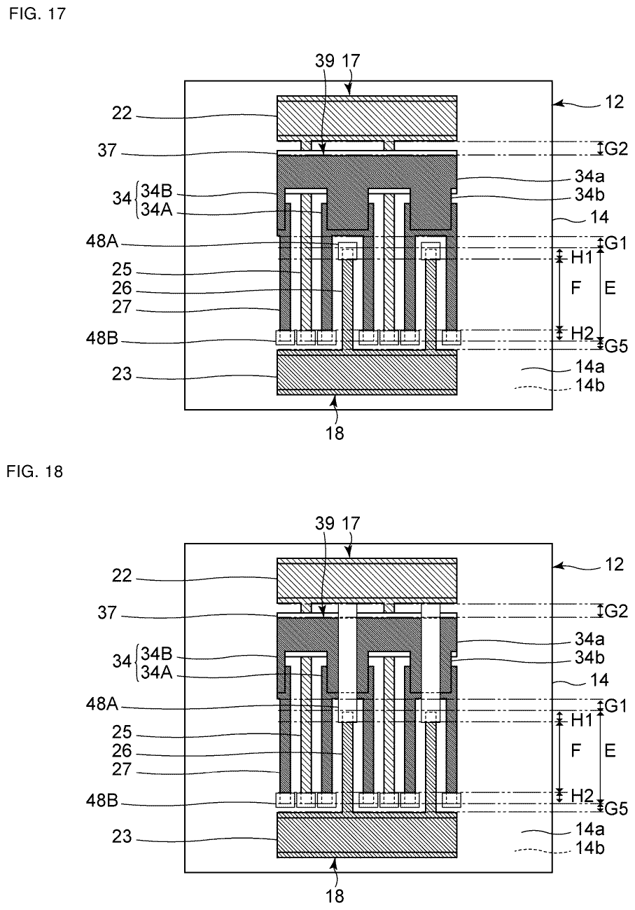

FIG. 17 is a schematic plan view of the acoustic wave device according to the ninth example embodiment.

The present example embodiment differs from the sixth example embodiment in the positions of the first mass-addition film 48A and the mass-addition film 48B. The acoustic wave device according to the present example embodiment has the same or substantially the same structure as the acoustic wave device according to the sixth example embodiment with the exception of the point described above. In the present example embodiment, the first gap region G1, the second gap region G2, and the fifth gap region G5 are provided.

The plurality of mass-addition films 48A are provided over the first gap region G1 and the first edge region H1. The plurality of mass-addition films 48A are arranged in the electrode finger orthogonal direction. On the other hand, the mass-addition films 48A are not provided in the second gap region G2.

Each of the mass-addition films 48A overlaps one of the plurality of first electrode fingers as viewed in the electrode finger extension direction. Each of the mass-addition films 48A overlaps one of the second electrode fingers 26 in plan view. The mass-addition film 48A may overlap the first electrode finger 25 or the third electrode finger 27 in plan view.

The plurality of mass-addition films 48B are provided over the fifth gap region G5 and the second edge region H2. The plurality of mass-addition films 48A are arranged in the electrode finger orthogonal direction.

Each of the mass-addition films 48B overlaps one of the plurality of first electrode fingers as viewed in the electrode finger extension direction. Some of the plurality of mass-addition films 48B overlap one of the plurality of first electrode fingers 25 in plan view. Each of the remaining mass-addition films 48B overlaps one of the third electrode fingers 27 in plan view. The mass-addition film 48B may overlap the second electrode finger 26 in plan view.

FIG. 18 is a schematic plan view of the acoustic wave device according to the tenth example embodiment.

The present example embodiment differs from the ninth example embodiment in that the mass-addition film 48A is provided over the first edge region H1, the first gap region G1, and the second gap region G2. The acoustic wave device according to the present example embodiment has the same or substantially the same structure as the acoustic wave device according to the ninth example embodiment with the exception of the point described above.

The mass-addition film 48A is continuously provided from the first edge region H1 to the second gap region G2 in the electrode finger extension direction. The mass-addition film 48A overlaps the connection electrode 24 closer to the first busbar 22 in plan view. The mass-addition film 48A is provided throughout the first gap region G1 and the second gap region G2 in the electrode finger extension direction.

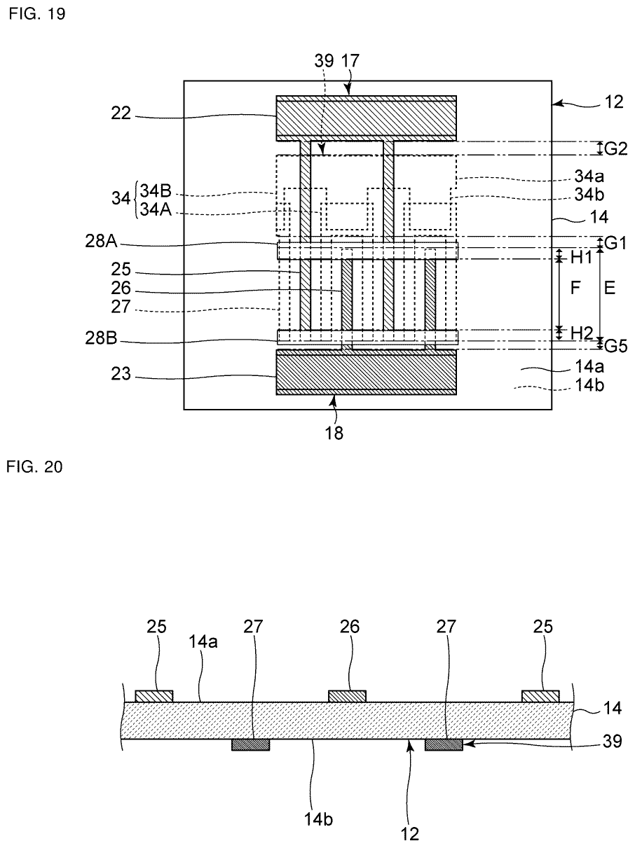

FIG. 19 is a schematic plan view of the first acoustic wave resonator according to an eleventh example embodiment of the present invention. FIG. 20 is a schematic elevational cross-sectional view illustrating the vicinity of the first to third electrode fingers in the eleventh example embodiment.

As illustrated in FIGS. 19 and 20, the present example embodiment differs from the sixth example embodiment in that the third electrode 39 is provided on the second main surface 14b of the piezoelectric layer 14. The acoustic wave device according to the present example embodiment has the same or substantially the same structure as the acoustic wave device according to the sixth example embodiment with the exception of the point described above.

The disposition in plan view of the third electrode 39 in the present example embodiment is the same or substantially the same as that in the sixth example embodiment. Accordingly, in plan view, the plurality of third electrode fingers 27 are provided on the second main surface 14b of the piezoelectric layer 14 so as to be disposed side by side with the first electrode fingers 25 and the second electrode fingers 26 in the direction in which the first electrode fingers 25 and the second electrode fingers 26 are arranged. The plurality of electrode fingers are arranged in the order of the first electrode finger 25, the third electrode finger 27, the second electrode finger 26, and the third electrode finger 27 that constitute one cycle in plan view when starting from the first electrode finger 25.

Even when the third electrode 39 is provided on the second main surface 14b of the piezoelectric layer 14, the gap regions can be defined as in the sixth example embodiment.

Specifically, the region, located between the ends of the plurality of second electrode fingers 26 and the third busbar 34 as the connection electrode in plan view, that extends in the electrode finger orthogonal direction is the first gap region G1. The region, located between the third busbar 34 and the first busbar 22 in plan view, that extends in the electrode finger orthogonal direction is the second gap region G2. The region, located between the ends of the plurality of first electrode fingers 25 and the second busbar 23 in the electrode finger extension direction in plan view, that extends in the electrode finger orthogonal direction is the fifth gap region G5.

The mass-addition film 28A is provided over the first gap region G1 and the first edge region H1. The mass-addition film 28B is provided over the fifth gap region G5 and the second edge region H2. Accordingly, also in the present example embodiment, when the acoustic wave device is used in the filter device, the size reduction of the filter device can be achieved and the degradation of filter characteristics can be reduced or prevented as in the sixth example embodiment.

The structure in which the third electrode 39 is provided on the second main surface 14b of the piezoelectric layer 14 is also applicable to other example embodiments of the present invention. For example, the third electrode 19 similar to that in the first example embodiment illustrated in FIG. 2 may be provided on the second main surface 14b. In this case, the first gap region G1, the second gap region G2, the third gap region G3, and the fourth gap region G4 are defined.

In example embodiments of the present invention, through-holes may be provided in the gap regions. In this case, the mass-addition film need not be provided. This example will be illustrated below.

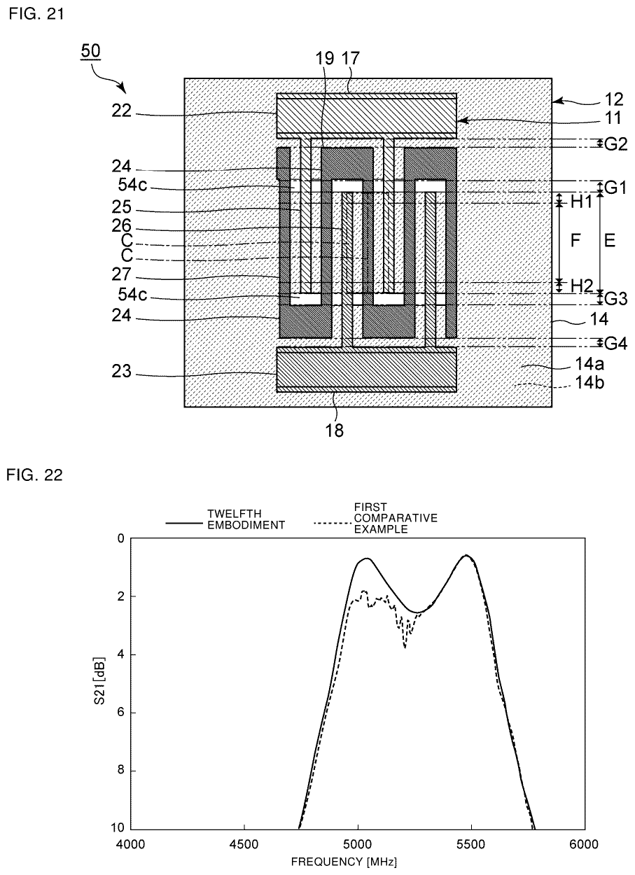

FIG. 21 is a schematic plan view of the acoustic wave device according to a twelfth example embodiment of the present invention. The electrodes and the piezoelectric layer 14 are hatched in FIG. 21. In schematic plan views other than FIG. 21, the electrodes and the piezoelectric layer 14 may be hatched.

The acoustic wave device 50 is an acoustically coupled filter. The acoustic wave device 50 includes the piezoelectric substrate 12 and the functional electrode 11 that are the same as or similar to those in the first example embodiment. In the acoustic wave device 50, the first gap region G1, the second gap region G2, the third gap region G3, and the fourth gap region G4 are provided.

The acoustic wave device 50 includes the plurality of excitation regions C and the overlap region E as in the first example embodiment. The acoustic wave device 50 is configured to be able to use the thickness-shear mode. However, the acoustic wave device 50 may also be configured to be able to use a plate wave, for example.

The piezoelectric layer 14 is made of Z-cut lithium niobate, for example. However, the piezoelectric layer 14 may also be made of rotated Y-cut lithium niobate, for example.

As illustrated in FIG. 21, a plurality of through-holes 54c are provided in the piezoelectric layer 14 as a piezoelectric film. Some of the plurality of through-holes 54c are located in the first gap region G1. More specifically, the through-holes 54c are located in all portions in the first gap region G1 in which the first electrode fingers 25, the second electrode fingers 26, or the third electrode fingers 27 are not provided.

The remaining through-holes 54c of the through-holes 54c are located in the third gap region G3. The through-holes 54c are located in all portions in the third gap region G3 in which the first electrode fingers 25, the second electrode fingers 26, or the third electrode fingers 27 are not provided. When the piezoelectric film is a laminated film including the piezoelectric layer 14, the through-holes 54c only need to pass through the laminated film.

The present example embodiment has the following structure. 1) The third electrode finger 27 of the third electrode 19 is provided between the first electrode finger 25 of the first interdigitated electrode 17 and the second electrode finger 26 of the second interdigitated electrode 18 in plan view. 2) In the first gap region G1 and the third gap region G3, the through-hole 54c is provided in the piezoelectric layer 14 as the piezoelectric film. 3) In the region in which the through-hole 54c is provided in plan view, the through-hole 54c is located in all of portions in which the first electrode fingers 25, the second electrode fingers 26, or the third electrode fingers 27 are not provided.

However, the through-hole 54c only needs to be provided in the piezoelectric layer 14 in at least one of the first gap region G1, the second gap region G2, the third gap region G3, and the fourth gap region G4. In this case, in the region in which the through-hole 54c is provided in plan view, the through-hole 54c only needs to be located in all of portions in which the electrode fingers are not provided. Since the structure described above is adopted, when the acoustic wave device 50 is used in the filter device, the size reduction of the filter device can be achieved and insertion loss can be reduced. This will be described below by comparison between the present example embodiment and the first comparative example.

The first comparative example differs from the twelfth example embodiment in that no through-holes are provided in the piezoelectric layer. In the first comparative example, the piezoelectric layer is made of Z-cut lithium niobate. The bandpass characteristics were compared between the twelfth example embodiment and the first comparative example. The design parameters of the acoustic wave device 50 having the structure of the twelfth example embodiment are shown below.
Piezoelectric layer: material LiNbO₃, Euler angles (φ, θ, ψ) (0°, 0°, 90°), thickness about 400 nm
First to third electrode fingers: layer structure Ti layer, AlCu layer, Ti layer as viewed from piezoelectric layer, thickness of each layer about 10 nm, about 390 nm, about 4 nm as viewed from piezoelectric layer
Order of first to third electrode fingers represented by potential connected thereto: IN, GND, OUT, GND, and so on
Center-to-center distance between adjacent electrode fingers: about 1.4 μm
Duty ratio: about 0.3

The design parameters in the first comparative example are the same or substantially the same as those in the twelfth example embodiment except that no through-holes are provided.

FIG. 22 is a diagram illustrating the bandpass characteristics of the acoustic wave devices according to the twelfth example embodiment and the first comparative example.

First, it can be seen that a filter waveform can be suitably obtained also in one acoustic wave device 50 according to the twelfth example embodiment as illustrated in FIG. 22. Accordingly, even if the number of acoustic wave resonators of the filter device 50 is small when the acoustic wave device is used in the filter device, a filter waveform can be suitably obtained. Accordingly, the size reduction of the filter device can be achieved.

In addition, it can be seen that loss near the center and on the low-frequency side of the pass band in the twelfth example embodiment is smaller than that in the first comparative example as illustrated in FIG. 22. Accordingly, when the acoustic wave device 50 is used in the filter device, insertion loss can be reduced.

A thirteenth example embodiment and a fourteenth example embodiment of the present invention in which only the disposition of the through-holes 54c differs from that of the twelfth example embodiment will be described below. In the thirteenth example embodiment and the fourteenth example embodiment, when the acoustic wave device is used in the filter device, the size reduction of the filter device can be achieved and insertion loss can be reduced as in the twelfth example embodiment.

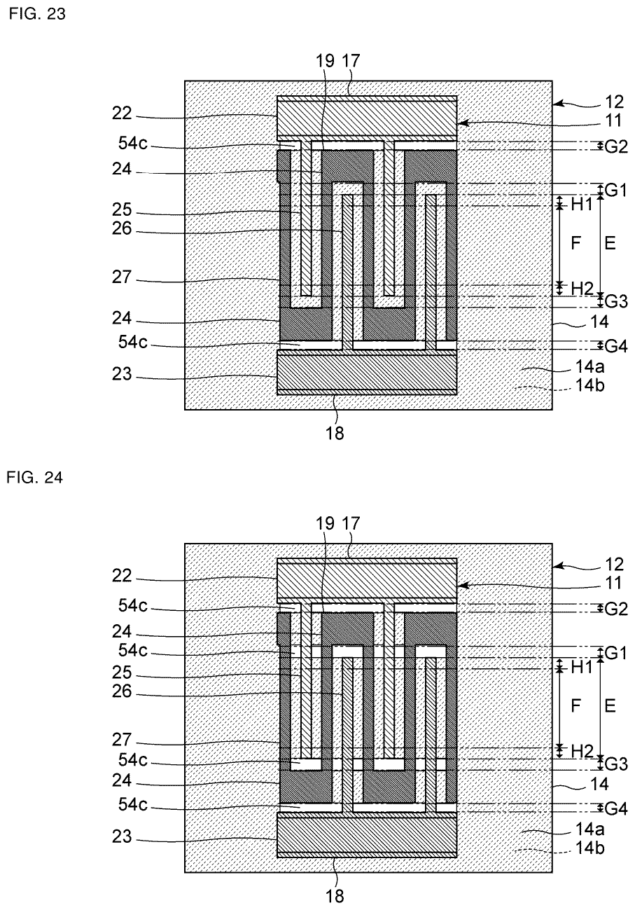

FIG. 23 is a schematic plan view of the acoustic wave device according to the thirteenth example embodiment.

In the present example embodiment, in the second gap region G2 and the fourth gap region G4, the plurality of through-holes 54c are provided in the piezoelectric layer 14 as a piezoelectric film. In the first gap region G1 and the third gap region G3, the through-holes 54c are not provided in the piezoelectric layer 14. In plan view, in the region in which the through-holes 54c are provided, the through-holes 54c are located in all of portions in which the electrode fingers are not provided.

FIG. 24 is a schematic plan view of the acoustic wave device according to the fourteenth example embodiment.

In the present example embodiment, in the first gap region G1, the second gap region G2, the third gap region G3, and the fourth gap region G4, the plurality of through-holes 54c are provided in the piezoelectric layer 14 as a piezoelectric film. In plan view, in the region in which the through-holes 54c are provided, the through-holes 54c are located in all of portions in which the electrode fingers are not provided.

The bandpass characteristics were compared between the present example embodiment and the first comparative example. The design parameters of the acoustic wave device having the structure of the present example embodiment are the same or substantially the same as the design parameters in the twelfth example embodiment concerning comparison illustrated in FIG. 22.

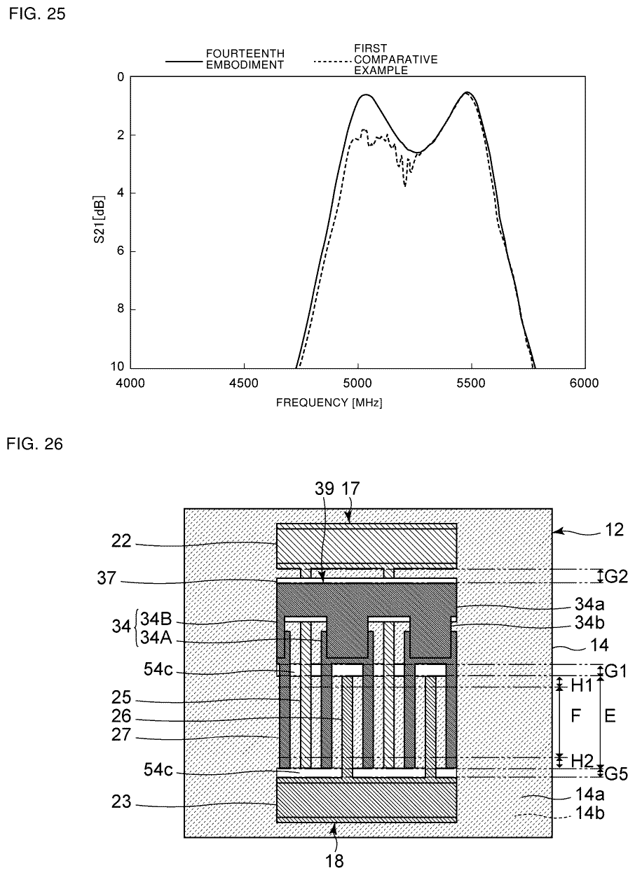

FIG. 25 is a diagram illustrating the bandpass characteristics of the acoustic wave devices according to the fourteenth example embodiment and the first comparative example.

It can be seen that loss near the center and on a low-frequency side of the pass band in the fourteenth example embodiment is smaller than that in the first comparative example as illustrated in FIG. 25.

The structure in which the through-holes are provided in the gap regions is applicable even when the gap regions are the first gap region G1, the second gap region G2, and the fifth gap region G5. This example will be described in the fifteenth example embodiment.

FIG. 26 is a schematic plan view of the acoustic wave device according to the fifteenth example embodiment.

In the present example embodiment, the structure of the functional electrode is the same as or similar to that in the sixth example embodiment. In the present example embodiment, the third gap region G3 and the fourth gap region G4 are not provided. In the present example embodiment, the first gap region G1, the second gap region G2, and the fifth gap region G5 are provided.

The present example embodiment has the following structure. 1) The third electrode finger 27 of the third electrode 19 is provided between the first electrode finger 25 of the first interdigitated electrode 17 and the second electrode finger 26 of the second interdigitated electrode 18 in plan view. 2) In the first gap region G1 and the fifth gap region G5, the through-hole 54c is provided in the piezoelectric layer 14 as the piezoelectric film. 3) In the region in which the through-hole 54c is provided in plan view, the through-hole 54c is located in all of portions in which the first electrode fingers 25, the second electrode fingers 26, or the third electrode fingers 27 are not provided.

In at least one of the first gap region G1, the second gap region G2, and the fifth gap region G5, the through-hole 54c only needs to be provided in the piezoelectric layer 14 as a piezoelectric film. In this case, in the region in which the through-hole 54c is provided in plan view, the through-hole 54c only needs to be located in all of portions in which the electrode fingers are not provided. Since the structure described above is provided, when the acoustic wave device is used in the filter device, the size reduction of the filter device can be achieved and insertion loss can be reduced.

The details of the thickness-shear mode will be described below by using an example in which the functional electrode is an IDT electrode. The IDT electrode does not include the third electrode finger. “Electrode” of the IDT electrode, which will be described later, corresponds to an electrode finger. The support in the following example corresponds to the support substrate. In the following description, the reference potential may be referred to as the ground potential.

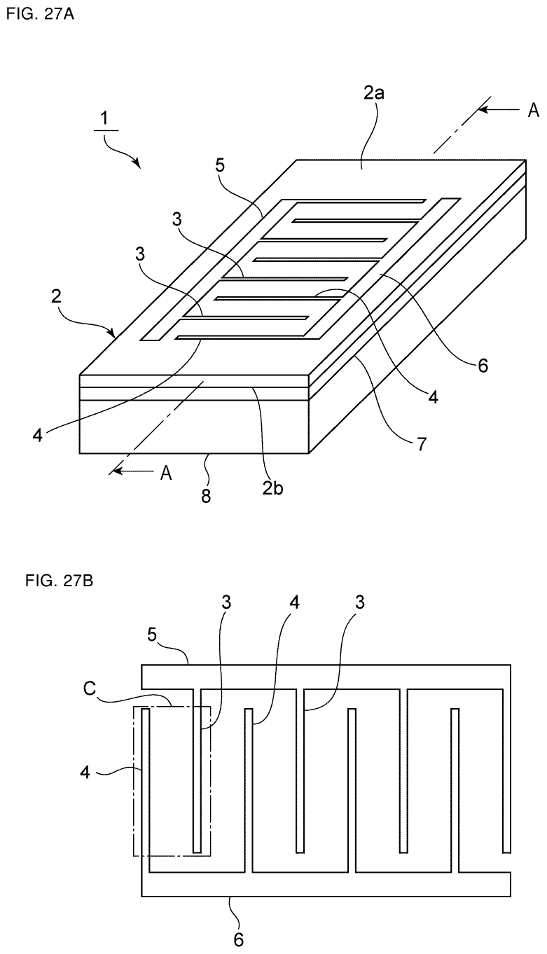

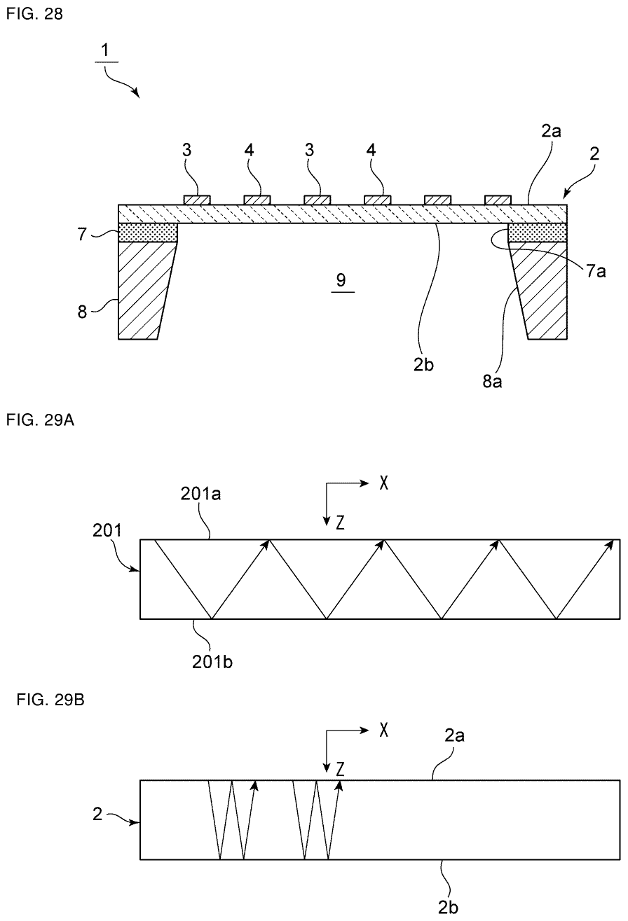

FIG. 27A is a schematic perspective view illustrating the appearance of the acoustic wave device that uses a bulk wave in the thickness-shear mode, and FIG. 27B is a plan view illustrating an electrode structure on a piezoelectric layer, and FIG. 28 is a cross-sectional view taken along line A-A in FIG. 27A.

The acoustic wave device 1 includes a piezoelectric layer 2 made of LiNbO₃, for example. The piezoelectric layer 2 may be made of LiTaO₃, for example. The cut angle of LiNbO₃ and LiTaO₃ is Z-cut but may also be a rotated Y-cut or an X-cut. The thickness of the piezoelectric layer 2 is not particularly limited but is, for example, preferably about 40 nm or more and about 1000 nm or less to effectively excite the thickness-shear mode, and more preferably about 50 nm or more and about 1000 nm or less. The piezoelectric layer 2 includes first and second main surfaces 2a and 2b that face away from each other. An electrode 3 and an electrode 4 are provided on the first main surface 2a. Here, the electrode 3 is an example of the first electrode, and the electrode 4 is an example of the second electrode. In FIGS. 27A and 27B, the plurality of electrodes 3 are connected to a first busbar 5. The plurality of electrodes 4 are connected to a second busbar 6. The plurality of electrodes 3 and the plurality of electrodes 4 are interdigitated with each other. The electrode 3 and the electrode 4 are rectangular or substantially rectangular and have a length direction. The electrode 3 and the electrode 4 adjacent thereto face each other in the direction orthogonal to the length direction. The length direction of the electrodes 3 and 4 and the direction orthogonal or substantially orthogonal to the length direction of the electrodes 3 and 4 intersect the thickness direction of the piezoelectric layer 2. Accordingly, it can be said that the electrode 3 and the electrode 4 adjacent thereto face each other in a direction intersecting the thickness direction of the piezoelectric layer 2. In addition, the length direction of the electrodes 3 and 4 may be replaced with the direction orthogonal or substantially orthogonal to the length direction of the electrodes 3 and 4 illustrated in FIGS. 27A and 27B. That is, in FIGS. 27A and 27B, the electrodes 3 and 4 may extend in the direction in which the first busbar 5 and the second busbar 6 extend. In this case, the first busbar 5 and the second busbar 6 extend in the direction in which the electrodes 3 and 4 extend in FIGS. 27A and 27B. In addition, a plurality of pairs of adjacent electrodes 3 and 4 connected to one potential and the other potential, respectively, are provided in a direction orthogonal or substantially orthogonal to the length direction of the electrodes 3 and 4. Here, the adjacent electrodes 3 and 4 refer to the electrodes 3 and 4 disposed with a gap therebetween instead of the electrodes 3 and 4 in direct contact with each other. In the adjacent electrodes 3 and 4, electrodes connected to a hot electrode or a ground electrode including other electrodes 3 and 4 are not disposed between the electrodes 3 and 4. The number of pairs does not need to be an integer and may be, for example, 1.5 pairs or 2.5 pairs. The center-to-center distance (that is, the pitch) between the electrodes 3 and 4 is, for example, preferably about 1 μm or more and about 10 μm or less. In addition, the widths of the electrodes 3 and 4, that is, the dimensions of the electrodes 3 and 4 in the facing direction are, for example, preferably about 50 nm or more and about 1000 nm or less, and more preferably about 150 nm or more and about 1000 nm or less. The center-to-center distance between the electrodes 3 and 4 is the distance between the middle of the dimension (width dimension) of the electrode 3 in the direction orthogonal or substantially orthogonal to the length direction of the electrode 3 and the middle of the dimension (width dimension) of the electrode 4 in the direction orthogonal or substantially orthogonal to the length direction of the electrode 4.

In addition, since the Z-cut piezoelectric layer is used in the acoustic wave device 1, the direction orthogonal or substantially orthogonal to the length direction of the electrodes 3 and 4 is orthogonal or substantially orthogonal to the polarization direction of the piezoelectric layer 2. The same does not apply when a piezoelectric body with another cut angle is used as the piezoelectric layer 2. Here, “orthogonal” is not limited to “strictly orthogonal” and may be “substantially orthogonal” (when the angle formed by the polarization direction and the direction orthogonal to the length direction of the electrodes 3 and 4 falls within the range of, for example, about 90°±10°).

A support 8 is laminated on the second main surface 2b of the piezoelectric layer 2 with an insulation layer 7 therebetween. The insulation layer 7 and the support 8 are frame-shaped and include through-holes 7a and 8a as illustrated in FIG. 28. As a result, a cavity portion 9 is provided. The cavity portion 9 is provided not to interfere with the vibration of the excitation region C of the piezoelectric layer 2. Accordingly, the support 8 is laminated on the second main surface 2b with the insulation layer 7 therebetween at a position that does not overlap a portion in which at least one pair of electrodes 3 and 4 is provided. The insulation layer 7 does not need to be provided. Accordingly, the support 8 can be laminated directly or indirectly on the second main surface 2b of the piezoelectric layer 2.

The insulation layer 7 is made of, for example, silicon oxide. However, for example, appropriate insulation materials other than silicon oxide, such as silicon oxynitride or alumina, can also be used. The support 8 is made of, for example, Si. The plane direction of the surface of Si closer to the piezoelectric layer 2 may be (100) or (110) or may be (111). The resistance of Si of the support 8 preferably has, for example, a high resistivity of about 4 kΩcm or more. However, the support 8 can be made of an appropriate insulation material or semiconductor material.

The material of the support 8 can be a piezoelectric body such as, for example, aluminum oxide, lithium tantalate, lithium niobate, or quartz, a ceramic such as alumina, magnesia, sapphire, silicon nitride, aluminum nitride, silicon carbide, zirconia, cordierite, mullite, steatite, or forsterite, a dielectric such as diamond or glass, or a semiconductor such as gallium nitride.

The plurality of electrodes 3 and 4 and the first and second busbars 5 and 6 are made of an appropriate metal or alloy, such as, for example, Al or Al—Cu alloy. In the acoustic wave device 1, the electrodes 3 and 4 and the first and second busbars 5 and 6 have, for example, a structure in which an Al film is laminated on a Ti film. A close contact layer other than a Ti film may be used.

An AC voltage is applied between the plurality of electrodes 3 and the plurality of electrodes 4 to perform driving. More specifically, an AC voltage is applied between the first busbar 5 and the second busbar 6. This can obtain resonance characteristics that uses a bulk wave in the thickness-shear mode excited by the piezoelectric layer 2. In addition, for example, in the acoustic wave device 1, when the thickness of the piezoelectric layer 2 is d and the center-to-center distance between any adjacent electrodes 3 and 4 of the plurality of pairs of electrodes 3 and 4 is p, d/p is set to be about 0.5 or less. Accordingly, a bulk wave in the thickness-shear mode is effectively excited, and good resonance characteristics can be obtained. More preferably, for example, d/p is about 0.24 or less and, in this case, more preferable resonant characteristics can be obtained.

Since the acoustic wave device 1 has the structure described above, even when the number of pairs of electrodes 3 and 4 is reduced for size reduction, the Q value is less likely to decrease. This is because the propagation loss is low even when the number of electrode fingers of the reflectors on both sides is reduced. In addition, the reason why the number of electrode fingers described above can be reduced is due to use of a bulk wave in the thickness-shear mode. The difference between a Lamb wave used in the acoustic wave device and the bulk wave in the thickness-shear mode will be described with reference to FIGS. 29A and 29B.

FIG. 29A is a schematic elevational cross-sectional view for describing a Lamb wave propagating through a piezoelectric film of an acoustic wave device as described in Japanese Unexamined Patent Application Publication No. 2012-257019. Here, the wave propagates through the piezoelectric film 201 as indicated by arrows. In the piezoelectric film 201, a first main surface 201a and a second main surface 201b face away from each other, and the thickness direction that connects the first main surface 201a and the second main surface 201b is a Z direction. An X direction is a direction in which the electrode fingers of the IDT electrode are arranged. As illustrated in FIG. 29A, the Lamb wave propagates in the X direction as illustrated in the drawing. Although the entire piezoelectric film 201 vibrates because of a plate wave, the wave propagates in the X direction. Accordingly, the reflectors are disposed on both sides to obtain resonance characteristics. Therefore, propagation loss of the wave occurs. When an attempt to achieve size reduction is made, that is, when the number of pairs of electrode fingers is reduced, the Q value decreases.

On the other hand, as illustrated in FIG. 29B, since vibration displacement occurs in a thickness-shear direction in the acoustic wave device 1, the wave propagates substantially in the direction connecting the first main surface 2a and the second main surface 2b of the piezoelectric layer 2, that is, in the Z direction, and resonates. That is, the X-direction component of the wave is significantly smaller than the Z-direction component thereof. In addition, since resonance characteristics are obtained by the propagation of the wave in the Z direction, even when the number of electrode fingers of the reflector is reduced, propagation loss is less likely to occur. In addition, even when the number of pairs of electrodes 3 and 4 is reduced to achieve size reduction, the Q value is less likely to decrease.

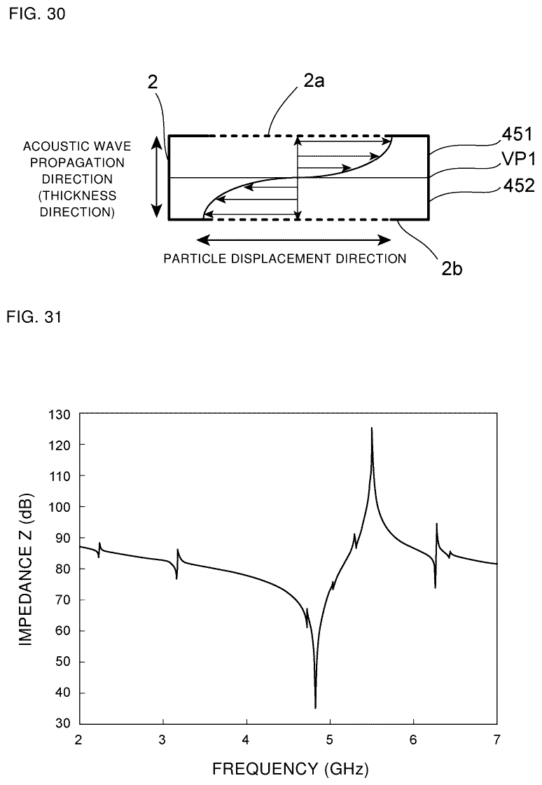

The amplitude direction of a bulk wave in the thickness-shear mode in a first region 451 included in the excitation region C of the piezoelectric layer 2 is opposite to that in a second region 452 included in the excitation region C, as illustrated in FIG. 30. FIG. 30 schematically illustrates a bulk wave when a voltage is applied between the electrode 3 and the electrode 4 such that the potential of the electrode 4 is higher than that of the electrode 3. The first region 451 is the region between the first main surface 2a and a virtual plane VP1, orthogonal or substantially orthogonal to the thickness direction of the piezoelectric layer 2, that divides the piezoelectric layer 2 into two in the excitation region C. The second region 452 is the region between the second main surface 2b and the virtual plane VP1 in the excitation region C.

Although at least one pair of electrodes 3 and 4 is disposed in the acoustic wave device 1 as described above, since the wave does not propagate in the X direction, the number of pairs of electrodes 3 and 4 does not need to be two or more. That is, at least one pair of electrodes only needs to be provided.

For example, the electrode 3 described above is an electrode connected to a hot potential, and the electrode 4 is an electrode connected to a ground potential. However, the electrode 3 may also be connected to the ground potential and the electrode 4 may also be connected to the hot potential. In the acoustic wave device 1, at least one pair of electrodes is connected to the hot potential and the ground potential as described above, and no floating electrode is provided.

FIG. 31 is a diagram illustrating resonance characteristics of the acoustic wave device illustrated in FIG. 28. The design parameters of the acoustic wave device 1 having the resonance characteristics are shown below.
Piezoelectric layer 2: LiNbO₃ with Euler angles (0°, 0°, 90°), thickness=about 400 nm.
Length of the region in which the electrode 3 and the electrode 4 overlap each other as viewed in a direction orthogonal to the length direction of the electrode 3 and the electrode 4, that is, the length of the excitation region C=about 40 μm, the number of pairs of electrodes 3 and 4=21, the center-to-center distance between the electrodes=about 3 μm, the width of the electrodes 3 and 4=about 500 nm, d/p=about 0.133
Insulation layer 7: silicon oxide film with a thickness of about 1 μm
Support 8: Si

The length of the excitation region C refers to the dimension of the excitation region C in the length direction of the electrodes 3 and 4.

In the acoustic wave device 1, the inter-electrode distance between the pair of electrodes 3 and 4 is the same or substantially the same among the plurality of pairs. That is, the electrode 3 and the electrode 4 are disposed at an equal or substantially equal pitch.

As is clear from FIG. 31, good resonance characteristics having a fractional bandwidth of about 12.5% are obtained even though no reflectors are present.

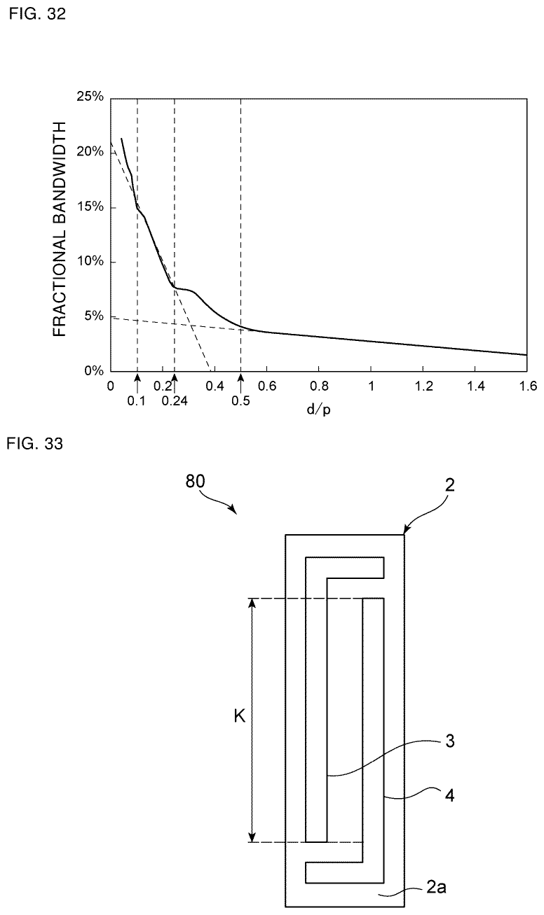

In addition, in the acoustic wave device 1, when the thickness of the piezoelectric layer 2 is d and the center-to-center distance between the electrode 3 and the electrode 4 is p, d/p is, for example, about 0.5 or less, and more preferably about 0.24 or less as described above. This will be described with reference to FIG. 32.

A plurality of acoustic wave devices have been obtained in the same or substantially the same manner as the acoustic wave device with the resonance characteristics illustrated in FIG. 31 but d/p is changed. FIG. 32 is a diagram illustrating the relationship between d/p and the fractional bandwidth of the acoustic wave device as a resonator.

As is clear from FIG. 32, when d/p>about 0.5, the fractional bandwidth is less than about 5% even if d/p is adjusted. On the other hand, when d/p≤about 0.5, the fractional bandwidth can be about 5% or more by d/p being changed within this range, that is, a resonator with a high coupling coefficient can be formed. Alternatively, when d/p is about 0.24 or less, the fractional bandwidth can be increased to about 7% or more. In addition, by d/p being adjusted within this range, a resonator with a wider fractional bandwidth can be obtained, and a resonator with a higher coupling coefficient can be achieved. Accordingly, it was discovered that a resonator with a high coupling coefficient that use a bulk wave in the thickness-shear mode can be formed by d/p being set to about 0.5 or less, for example.

FIG. 33 is a plan view of the acoustic wave device that uses a bulk wave in the thickness-shear mode. In an acoustic wave device 80, a pair of electrodes 3 and 4 is provided on the first main surface 2a of the piezoelectric layer 2. K in FIG. 33 represents the overlap width. As described above, in the acoustic wave device according to example embodiments of the present invention, the number of pairs of electrodes may be one. Even in this case, for example, when d/p is about 0.5 or less, a bulk wave in the thickness-shear mode can be effectively excited.

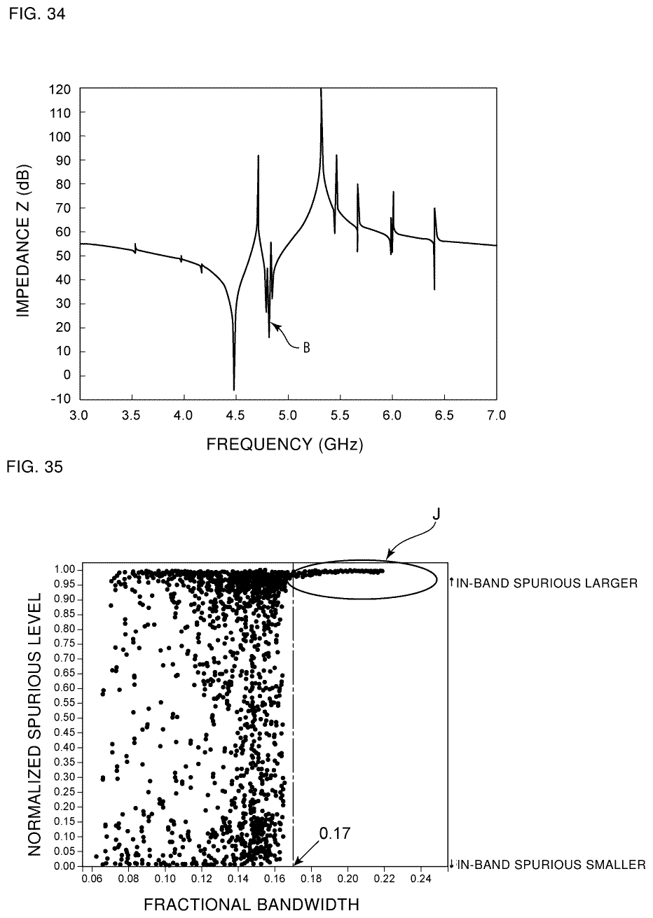

In the acoustic wave device 1, preferably, the metallization ratio MR of any adjacent electrodes 3 and 4 of the plurality of electrodes 3 and 4 with respect to the excitation region C in which the electrodes 3 and 4 overlap each other as viewed in a direction in which the adjacent electrodes 3 and 4 face each other satisfies MR≤about 1.75(d/p)+0.075, for example. In this case, a spurious response can be effectively reduced. This will be described with reference to FIGS. 34 and 35. FIG. 34 is a reference diagram illustrating an example of the resonance characteristics of the acoustic wave device 1 described above. The spurious response indicated by arrow B appears between the resonant frequency and the anti-resonant frequency. It is assumed that d/p is about 0.08 and the Euler angles of LiNbO₃ are (0°, 0°, 90°). In addition, it is assumed that the metallization ratio MR described above is about 0.35.

The metallization ratio MR will be described with reference to FIG. 27B. In the electrode structure in FIG. 27B, when attention is focused on a pair of electrodes 3 and 4, it is assumed that only this pair of electrodes 3 and 4 is provided. In this case, the portion surrounded by the dotted line is the excitation region C. This excitation region C is the region of the electrode 3 that overlaps the electrode 4, the region of the electrode 4 that overlaps the electrode 3, and the region between the electrode 3 and the electrode 4 in which the electrode 3 and the electrode 4 overlap each other, as viewed in the direction orthogonal to the length direction of the electrodes 3 and 4, that is, in the facing direction. In addition, the ratio of the areas of the electrodes 3 and 4 in the excitation region C to the area of the excitation region C is the metallization ratio MR. That is, the metallization ratio MR is the ratio of the area of the metallization portion to the area of the excitation region C.

When a plurality of pairs of electrodes are provided, MR may be the ratio of the metallization portions included in all excitation regions to the sum of the areas of the excitation regions.

FIG. 35 is a diagram illustrating the relationship between the fractional bandwidth when many acoustic wave devices are formed according to the structure of the acoustic wave device 1 and the phase rotation amount of the impedance of spurious normalized by about 180 degrees as the level of the spurious. It should be noted that the fractional bandwidth has been adjusted by the film thickness of the piezoelectric layer and the dimensions of the electrodes being changed. In addition, FIG. 35 illustrates the results obtained when a piezoelectric layer made of Z-cut LiNbO₃ is used, but similar trends are also obtained when a piezoelectric layer with a different cut angle is used.

In the region in an ellipse J in FIG. 35, a large spurious response with a level of about 1.0 appears. As is clear from FIG. 35, when the fractional bandwidth exceeds about 0.17 (that is, about 17%), a large spurious response with a level of about 1 or more appears in the pass band even when parameters of the fractional bandwidth are changed. That is, a large spurious response indicated by arrow B appears within the band as the resonance characteristics illustrated in FIG. 34. Accordingly, the fractional bandwidth is, for example, preferably about 17% or less. In this case, a spurious response can be reduced by the film thickness of the piezoelectric layer 2 and the dimensions of the electrodes 3 and 4 being adjusted.

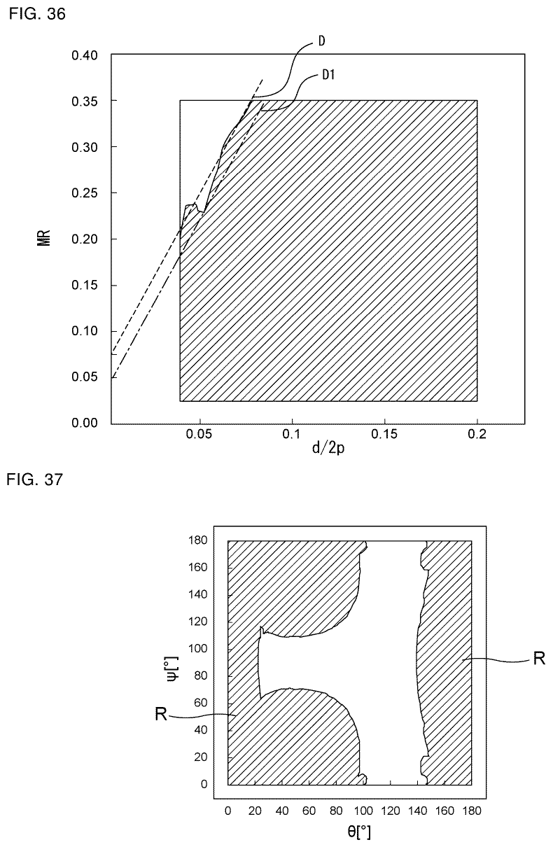

FIG. 36 is a diagram illustrating the relationship between d/2p, the metallization ratio (MR), and the fractional bandwidth. In the acoustic wave device described above, various acoustic wave devices with different d/2p values and MR values were formed, and the fractional bandwidth of each of them was measured. In the hatched region on the right side of a dashed line D in FIG. 36, the fractional bandwidth is about 17% or less. The boundary between the hatched region and the non-hatched region is represented by MR=about 3.5(d/2p)+0.075. That is, MR=about 1.75(d/p)+0.075 is satisfied. Accordingly, for example, MR≤about 1.75(d/p)+0.075 is preferably satisfied. In this case, the fractional bandwidth can be easily set to about 17% or less. The region on the right side of a dot-dash line D1 in FIG. 36 represented by MR=about 3.5(d/2p)+0.05 is more preferable, for example. That is, when MR≤about 1.75 (d/p)+0.05 is satisfied, the fractional bandwidth can be about 17% or less with greater certainty.

FIG. 37 is a diagram illustrating a map of the fractional bandwidth with respect to the Euler angles (0°, θ, ψ) of LiNbO₃ when d/p is infinitely brought close to 0. A plurality of hatched regions R in FIG. 37 are region in which a fractional bandwidth of about 2% or more is obtained. When φ of the Euler angles (φ, θ, ψ) falls within the range of about 0°±5°, the relationship between θ and ψ and the fractional bandwidth is the same or substantially the same as the relationship illustrated in FIG. 37. Even when the piezoelectric layer is made of, for example, lithium tantalate (LiTaO₃), the relationship between θ and ψ of the Euler angles (within the range of 0°±5°, θ, ψ) and BW is the same or substantially the same as the relationship illustrated in FIG. 37.

Accordingly, when φ of the Euler angle (φ, θ, ψ) of lithium niobate or lithium tantalate that define the piezoelectric layer falls within the range of about 0°±5° and θ and φ fall within one of the plurality of regions R illustrated in FIG. 37, it is preferable because the fractional bandwidth can be sufficiently widened.

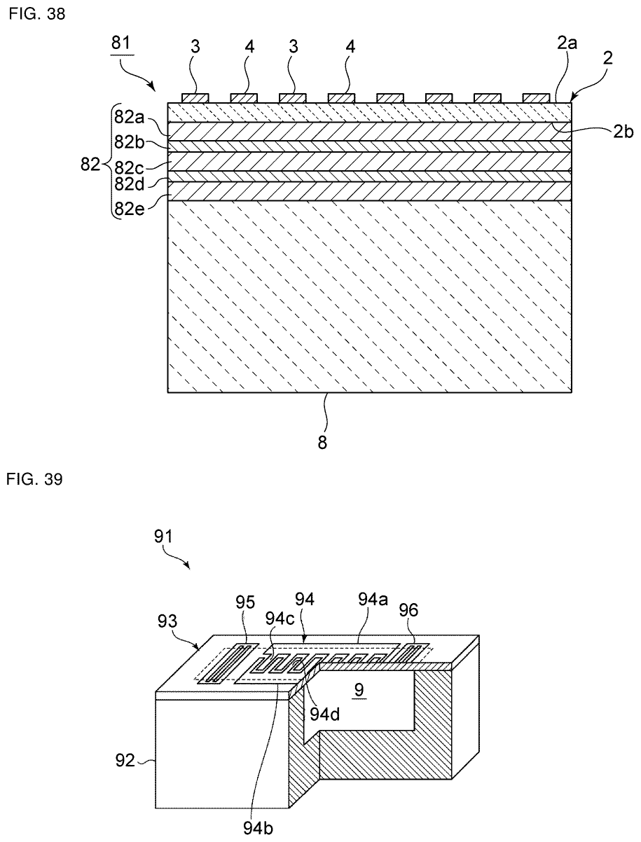

FIG. 38 is an elevational cross-sectional view of the acoustic wave device including an acoustic multilayer film.

In the acoustic wave device 81, an acoustic multilayer film 82 is laminated on the second main surface 2b of the piezoelectric layer 2. The acoustic multilayer film 82 has a laminated structure in which low-acoustic-impedance layers 82a, 82c, and 82e with relatively low acoustic impedance and high-acoustic-impedance layers 82b and 82d with relatively high acoustic impedance are laminated together. When the acoustic multilayer film 82 is used, a bulk wave in the thickness-shear mode can be confined in the piezoelectric layer 2 without using the cavity portion 9 of the acoustic wave device 1. Also in the acoustic wave device 81, resonance characteristics based on a bulk wave of the thickness-shear mode can be obtained by d/p being set to about 0.5 or less. The number of the low-acoustic-impedance layers 82a, 82c, and 82e and the high-acoustic-impedance layers 82b and 82d laminated together in the acoustic multilayer film 82 is not particularly limited. At least one of the high-acoustic-impedance layers 82b and 82d only needs to be disposed further away from the piezoelectric layer 2 than the low-acoustic-impedance layers 82a, 82c, and 82e.

The low-acoustic-impedance layers 82a, 82c, and 82e and the high-acoustic-impedance layers 82b and 82d can be made of appropriate materials as long as the relationship of acoustic impedance described above is satisfied. For example, the material of the low-acoustic-impedance layers 82a, 82c, and 82e may be silicon oxide, silicon oxynitride, or the like. In addition, the material of the high-acoustic-impedance layers 82b and 82d may be alumina, silicon nitride, or a metal.

FIG. 39 is a partially cutaway perspective view for describing an acoustic wave device that uses a Lamb wave.

An acoustic wave device 91 includes a support substrate 92. The support substrate 92 includes an open recessed portion in the upper surface. A piezoelectric layer 93 is laminated on the support substrate 92. This defines the cavity portion 9. An IDT electrode 94 is provided on the piezoelectric layer 93 above the cavity portion 9. Reflectors 95 and 96 are provided on both sides in the acoustic wave propagation direction of the IDT electrode 94. In FIG. 39, the outer peripheral edge of the cavity portion 9 is indicated by a dashed line. Here, the IDT electrode 94 includes first and second busbars 94a and 94b, a plurality of first electrode fingers 94c, and a plurality of second electrode fingers 94d. The plurality of first electrode fingers 94c are connected to the first busbar 94a. The plurality of second electrode fingers 94d are connected to the second busbar 94b. The plurality of first electrode fingers 94c and the plurality of second electrode fingers 94d are interdigitated with each other.

In the acoustic wave device 91, a Lamb wave as a plate wave is excited by an alternating electric field being applied to the IDT electrode 94 above the cavity portion 9 described above. In addition, since the reflectors 95 and 96 are provided on both sides, resonance characteristics due to the Lamb wave described above can be obtained.

As described above, an acoustic wave device according to an example embodiment of the present invention may use a plate wave. In the example illustrated in FIG. 39, the IDT electrode 94, the reflector 95, and the reflector 96 are provided on the main surface corresponding to the first main surface 14a of the piezoelectric layer 14 illustrated in FIG. 1 and the like. On the other hand, in an acoustic wave device according to an example embodiment of the present invention, a pair of interdigitated electrodes is provided on the first main surface 14a, and the plurality of third electrode fingers are provided on the first main surface 14a or the second main surface 14b. When an acoustic wave device according to an example embodiment of the present invention uses a plate wave, the reflector 95 and the reflector 96 described above only need to be provided on the first main surface 14a of the piezoelectric layer 14 according to the first to fifteenth example embodiments. In this case, the pair of interdigitated electrodes and the plurality of third electrode fingers only need to be sandwiched between the reflector 95 and the reflector 96 in the electrode finger orthogonal direction in plan view.

In the acoustic wave devices according to the first to fifteenth example embodiments, the acoustic multilayer film 82 illustrated in FIG. 38 as an acoustic reflection film may be provided between, for example, the support and the piezoelectric layer as a piezoelectric film. Specifically, the support and the piezoelectric film may be disposed such that at least a portion of the support and at least a portion of the piezoelectric film face each other with the acoustic multilayer film 82 therebetween. In this case, a low-acoustic-impedance layer and a high-acoustic-impedance layer only need to be alternately laminated with each other in the acoustic multilayer film 82. The acoustic multilayer film 82 may be an acoustic reflection portion of the acoustic wave device.

In the acoustic wave devices according to the first to fifteenth example embodiments that use a bulk wave in the thickness-shear mode, for example, d/p is preferably about 0.5 or less, and more preferably about 0.24 or less, as described above. As a result, better resonance characteristics can be obtained.

In addition, in the excitation region of each of the acoustic wave devices according to the first to fifteenth example embodiments that use a bulk wave in the thickness-shear mode, for example, MR≤about 1.75(d/p)+0.075 is preferably satisfied as described above. More specifically, when the metallization ratio (MR) of the first and third electrode fingers and the second and third electrode fingers with respect to the excitation region is MR, for example, MR≤about 1.75(d/p)+0.075 is preferably satisfied. In this case, a spurious response can be reduced or prevented with greater certainty.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric film including a piezoelectric layer including lithium niobate;
a first interdigitated electrode on the piezoelectric layer, and including a first busbar and a plurality of first electrode fingers each including one end connected to the first busbar;
a second interdigitated electrode on the piezoelectric layer, and including a second busbar and a plurality of second electrode fingers each including one end connected to the second bus bar, the plurality of second electrode fingers being interdigitated with the plurality of first electrode fingers; and
a third electrode including a plurality of third electrode fingers and a connection electrode, the plurality of third electrode fingers being provided on the piezoelectric layer side by side with the first electrode fingers and the second electrode fingers in a direction in which the first electrode fingers and the second electrode fingers are arranged in plan view, the connection electrode connecting adjacent third electrode fingers to each other, the third electrode being connected to a potential different from a potential of the first interdigitated electrode and a potential of the second interdigitated electrode; wherein
one of the first interdigitated electrode and the second interdigitated electrode is connected to an input potential and another of the second interdigitated electrode and the second interdigitated electrode is connected to an output potential;
the first electrode fingers, the second electrode fingers, and the third electrode fingers are arranged in an order of the first electrode finger, the third electrode finger, the second electrode finger, and the third electrode finger defining one cycle when starting from the first electrode finger;
the connection electrode connects ends of adjacent third electrode fingers closer to at least the first busbar to each other, and the connection electrode is located between at least the first busbar and ends of the plurality of second electrode fingers;
when a direction in which the first electrode fingers, the second electrode fingers, and the third electrode fingers extend is an electrode finger extension direction, and a direction orthogonal or substantially orthogonal to the electrode finger extension direction is an electrode finger orthogonal direction, a region, located between the ends of the plurality of second electrode fingers and the connection electrode in the electrode finger extension direction in plan view, that extends in the electrode finger orthogonal direction is a first gap region, a region, located between the connection electrode and the first busbar, that extends in the electrode finger orthogonal direction is a second gap region; and
a mass-addition film is provided in at least a portion of at least one of the first gap region, the second gap region, and a region between ends of the plurality of first electrode fingers and the second busbar in the electrode finger extension direction in plan view, does not include the connection electrode, and extends in the electrode finger orthogonal direction.

2. The acoustic wave device according to claim 1, wherein
a plurality of connection electrodes are provided, the connection electrode being one of the plurality of connection electrodes, and some of the plurality of connection electrodes connect the ends of the adjacent third electrode fingers closer to the second busbar to each other; and
a region, located between the ends of the plurality of first electrode fingers and the second busbar and between the ends of the plurality of first electrode fingers and the connection electrode in the electrode finger extension direction in plan view, that extends in the electrode finger orthogonal direction is a third gap region, and a region, located between the connection electrode and the second busbar, that extends in the electrode finger orthogonal direction is a fourth gap region.

3. The acoustic wave device according to claim 2, wherein the mass-addition film is provided in the first gap region and the third gap region.

4. The acoustic wave device according to claim 3, wherein the mass-addition film is also provided in the second gap region and the fourth gap region.

5. The acoustic wave device according to claim 1, wherein
of ends of the third electrode fingers adjacent to each other, the connection electrode connects only ends closer to the first busbar; and
a region, located between the ends of the plurality of first electrode fingers and the second busbar in the electrode finger extension direction in plan view, that extends in the electrode finger orthogonal direction, is a fifth gap region.

6. The acoustic wave device according to claim 5, wherein the mass-addition film is provided in the first gap region and the fifth gap region.

7. The acoustic wave device according to claim 6, wherein the mass-addition film is also provided in the second gap region.

8. The acoustic wave device according to claim 3, wherein
a region in which the first electrode fingers and the second electrode fingers overlap each other in the electrode finger orthogonal direction is an overlap region;
the overlap region includes a central region and a first edge region and a second edge region on both sides of the central region in the electrode finger extension direction so as to face each other; and
the mass-addition film is provided in the first edge region and the second edge region.

9. The acoustic wave device according to claim 1, wherein the mass-addition film overlaps the plurality of first electrode fingers, the plurality of second electrode fingers, and the plurality of third electrode fingers as viewed in the electrode finger extension direction.

10. The acoustic wave device according to claim 1, wherein
a plurality of mass-addition films are arranged in the electrode finger orthogonal direction, the mass-addition film being one of the plurality of mass-addition films; and
one of the mass-addition films overlaps one of the plurality of first electrode fingers, the plurality of second electrode fingers, and the plurality of third electrode fingers as viewed in the electrode finger extension direction.

11. The acoustic wave device according to claim 1, wherein the mass-addition film includes at least one dielectric of silicon dioxide, tungsten oxide, niobium oxide, tantalum oxide, or hafnium oxide.

12. An acoustic wave device comprising:
a piezoelectric film including a piezoelectric layer including lithium niobate;
a first interdigitated electrode on the piezoelectric layer, and including a first busbar and a plurality of first electrode fingers each including one end connected to the first busbar;
a second interdigitated electrode on the piezoelectric layer, and including a second busbar and a plurality of second electrode fingers each including one end connected to the second bus bar, the plurality of second electrode fingers being interdigitated with the plurality of first electrode fingers; and
a third electrode including a plurality of third electrode fingers and a connection electrode, the plurality of third electrode fingers being provided on the piezoelectric layer side by side with the first electrode fingers and the second electrode fingers in a direction in which the first electrode fingers and the second electrode fingers are arranged in plan view, the connection electrode connecting adjacent third electrode fingers to each other, the third electrode being connected to a potential different from a potential of the first interdigitated electrode and a potential of the second interdigitated electrode; wherein
one of the first interdigitated electrode and the second interdigitated electrode is connected to an input potential and another of the second interdigitated electrode and the second interdigitated electrode is connected to an output potential;
the first electrode fingers, the second electrode fingers, and the third electrode fingers are arranged in an order of the first electrode finger, the third electrode finger, the second electrode finger, and the third electrode finger defining one cycle when starting from the first electrode finger;
the connection electrode connects ends of the adjacent third electrode fingers closer to at least the first busbar to each other, and the connection electrode is located between at least the first busbar and ends of the plurality of second electrode fingers;
when a direction in which the first electrode fingers, the second electrode fingers, and the third electrode fingers extend is an electrode finger extension direction, and a direction orthogonal or substantially orthogonal to the electrode finger extension direction is an electrode finger orthogonal direction, a region, located between the ends of the plurality of second electrode fingers and the connection electrode in the electrode finger extension direction in plan view, that extends in the electrode finger orthogonal direction is a first gap region, a region, located between the connection electrode and the first busbar, that extends in the electrode finger orthogonal direction is a second gap region;
a through-hole is provided in the piezoelectric film in at least one of the first gap region, the second gap region, and a region between ends of the plurality of first electrode fingers and the second busbar in the electrode finger extension direction in plan view, does not include the connection electrode, and extends in the electrode finger orthogonal direction; and
in the region in which the through-hole is provided in plan view, the through-hole is located in all of portions in which the first electrode fingers, the second electrode fingers, or the third electrode fingers are not provided.

13. The acoustic wave device according to claim 12, wherein
a plurality of connection electrodes are provided, the connection electrode being one of the plurality of connection electrodes, and some of the plurality of connection electrodes connect ends of the adjacent third electrode fingers closer to the second busbar to each other; and
a region, located between the ends of the plurality of first electrode fingers and the second busbar in plan view and between the ends of the plurality of first electrode fingers and the connection electrode in the electrode finger extension direction, that extends in the electrode finger orthogonal direction is a third gap region, and a region, located between the connection electrode and the second busbar, that extends in the electrode finger orthogonal direction is a fourth gap region.

14. The acoustic wave device according to claim 13, wherein the through-hole is provided in the piezoelectric film in each of the first gap region and the third gap region.

15. The acoustic wave device according to claim 14, wherein the through-hole is also provided in the piezoelectric film in the second gap region and the fourth gap region.

16. The acoustic wave device according to claim 12, wherein
the connection electrode connects only the ends of the adjacent third electrode fingers closer to the first busbar of the ends of the adjacent third electrode fingers to each other; and
a region, located between the ends of the plurality of first electrode fingers and the second busbar in the electrode finger extension direction in plan view, that extends in the electrode finger orthogonal direction is a fifth gap region.

17. The acoustic wave device according to claim 16, wherein the through-hole is provided in the piezoelectric film in each of the first gap region and the fifth gap region.

18. The acoustic wave device according to claim 17, wherein the through-hole is also provided in the piezoelectric film in the second gap region.

19. The acoustic wave device according to claim 1, wherein the acoustic wave device is structured to generate a bulk wave in a thickness-shear mode.

20. The acoustic wave device according to claim 1, further comprising:
a support laminated on the piezoelectric film; wherein
an acoustic reflection portion is provided at a position on the support overlapping the plurality of first electrode fingers, the plurality of second electrode fingers, and the plurality of third electrode fingers in plan view as viewed in a direction in which the support and the piezoelectric film are laminated together; and
when a longest distance of center-to-center distances between the first electrode fingers and the third electrode fingers adjacent to each other and center-to-center distances between the second electrode fingers and the third electrode fingers adjacent to each other is p and a thickness of the piezoelectric film is d, d/p is about 0.5 or less.

21. The acoustic wave device according to claim 20,
wherein d/p is about 0.24 or less.

22. The acoustic wave device according to claim 20, wherein the acoustic reflection portion includes a cavity portion, and the support and the piezoelectric film are positioned such that a portion of the support and a portion of the piezoelectric film face each other with the cavity portion therebetween.

23. The acoustic wave device according to claim 20, wherein
the acoustic reflection portion is an acoustic reflection film including a high-acoustic-impedance layer with a relatively high acoustic impedance and a low-acoustic-impedance layer with a relatively low acoustic impedance; and
the support and the piezoelectric film are positioned such that at least a portion of the support and at least a portion of the piezoelectric film face each other with the acoustic reflection film therebetween.

24. The acoustic wave device according to claim 20, wherein
an excitation region is a region in which the first electrode fingers and the third electrode fingers adjacent to each other overlap each other in the electrode finger orthogonal direction;
the region is present between centers of the first electrode fingers and the third electrode fingers adjacent to each other;
the region is a region in which the second electrode fingers and the third electrode fingers adjacent to each other overlap each other in the electrode finger orthogonal direction;
the region is present between centers of the second electrode fingers and the third electrode fingers adjacent to each other; and
when a metallization ratio of the first and third electrode fingers and the second and third electrode fingers with respect to the excitation region is MR, MR≤about 1.75(d/p)+0.075 is satisfied.

25. The acoustic wave device according to claim 1, wherein
Euler angles (φ, θ, ψ) of lithium niobate of the piezoelectric layer are within a range of expression (1), expression (2), or expression (3):
(0°±10°, 0° to 25°, any given ψ) expression (1);
(0°±10°, 250 to 100°, 0° to 75°[(1−(θ−50)²/2500)]^{1/2} or 180°−75°[(1−(θ−50)²/2500)]^{1/2} to 180°) expression (2);
and
(0°±10°, 180°−40°[(1−(ψ−90)²/8100)]^{1/2} to 180°, any given ψ) expression (3).
